(19) United States
(12) Patent Application Publication
(10) Pub. No.: US 2023/0078324 A1
(43) Pub. Date: Mar. 16, 2023

(54) MASK

(71) Applicant: Murata Manufacturing Co., Ltd., Nagaokakyo-shi (JP)

(72) Inventors: Masayoshi TAKAGI, Nagaokakyo-shi (JP); Kenichiro TAKUMI, Nagaokakyo-shi (JP); Kanako ANDO, Nagaokakyo-shi (JP); Masayuki TSUJI, Nagaokakyo-shi (JP); Ryosuke EBINA, Osaka (JP)

(21) Appl. No.: 17/982,720

(22) Filed: Nov. 8, 2022

Related U.S. Application Data
(63) Continuation of application No. PCT/JP2022/016377, filed on Mar. 24, 2022.

(30) Foreign Application Priority Data
Apr. 8, 2021 (JP) 2021-065672

(51) Int. Cl. A41D 13/11; H01L 41/18

(52) U.S. Cl. CPC A41D 13/1192; H01L 41/183

(57) ABSTRACT

A mask that exhibits a more improved antibacterial effect by more efficiently expanding and contracting a body of the mask in the periphery of the nose and mouth area of the mask without using a drug such as an antibacterial agent and/or an antiviral agent. The mask includes: a body including a yarn having a potential generating filament; and at least one dart that extends from an edge portion of the body towards a central portion of the body.

### CROSS REFERENCE TO RELATED APPLICATIONS

The present application is a continuation of International application No. PCT/JP2022/016377, filed Mar. 24, 2022, which claims priority to Japanese Patent Application No. 2021-065672, filed Apr. 8, 2021, the entire contents of each of which are incorporated herein by reference.

### FIELD OF THE INVENTION

The present disclosure relates to a mask. More specifically, the present disclosure relates to a mask in which a mask main body includes a yarn formed of potential generating filaments.

### BACKGROUND OF THE INVENTION

There are known masks and fabrics of various shapes and structures having functions such as antibacterial property and/or antiviral property (refer to Patent Documents 1 to 10).
Patent Document 1: JP-A-2011-167226
Patent Document 2: JP-A-2019-77970
Patent Document 3: JP-A-2019-77971
Patent Document 4: JP-A-2017-101374
Patent Document 5: JP-A-2008-272375
Patent Document 6: JP-A-2003-741
Patent Document 7: JP-A-2011-92282
Patent Document 8: JP-A-2019-26957
Patent Document 9: JP-A-2020-193429
Patent Document 10: Japanese Patent No. 6399274

### SUMMARY OF THE INVENTION

Patent Document 1 discloses an antibacterial mask having a two-layer structure including a first base cloth holding a silver-based inorganic antibacterial agent and a second base cloth on which carboxylic acid is precipitated.

Patent Document 2 discloses a mask having a two-layer structure formed of a bonding sheet.

Patent Document 3 discloses a mask having a three-layer structure formed of a bonding sheet.

Patent Document 4 discloses an antiviral hygiene mask including two or more layers of a knitted fabric with an antiviral agent and a knitted fabric without an antiviral agent.

Patent Document 5 discloses a hygiene mask including a mask main body formed by folding a knitted fabric a plurality of times into a predetermined shape and stitching a predetermined portion.

Patent Document 6 discloses a hygiene mask in which at least two horizontally extending pleats are formed.

Patent Document 7 discloses a mask including a shape retaining material.

Patent Document 8 discloses a mask having a pleated structure.

Patent Document 9 discloses an antibacterial mask having a filter including a first piezoelectric fiber and a second piezoelectric fiber that generate a potential by expansion and contraction.

Patent Document 10 discloses a fabric including a first yarn and a second yarn that generate charges having different polarities by energy from the outside.

The inventors of the present application have noticed that known masks and cloth have problems to be overcome, and have found the need to take measures therefor. Specifically, the inventors of the present application have found that there are the following problems.

Patent Documents 1 to 8 disclose a mask having a multilayer structure and pleats, a mask including a shape retaining material, and the like. However, there is a limit to further improvement of the antibacterial effect and the antiviral effect by such a configuration.

In addition, in a mask in which an antibacterial agent or an antiviral agent disclosed in Patent Document 1, Patent Document 4, or the like is applied to a fabric, there is a possibility that an added drug is mixed into a human body to cause harm, and thus safety is low.

Patent Documents 9 and 10 disclose an antibacterial mask using piezoelectric fibers, a fabric, and the like. However, in order to obtain a desired piezoelectric antibacterial effect, it has been found that it is important to further efficiently stretch and contract the fabric around the nose and mouth of the mask to enhance the piezoelectric antibacterial effect.

The present disclosure has been made in view of such problems. That is, a main object of the present disclosure is to provide a mask that exhibits a more improved antibacterial effect by more efficiently expanding and contracting the mask main body in the periphery of the nose and mouth of the mask without using a drug such as an antibacterial agent and/or an antiviral agent.

The inventors of the present application have attempted to solve the above problems by addressing the problems in a new direction instead of addressing the problems in an extension of the conventional technique. As a result, the inventors of the present invention have reached the invention of a mask that has achieved the above main object.

First, the inventors of the present application have studied to further efficiently stretch and contract the mask main body at a central portion of the mask main body including the yarn (hereinafter, it may be referred to as “piezoelectric yarn”) formed of potential generating filaments, particularly at the peripheral portion of the nose and mouth of the mask main body. With such a configuration, it was considered that the central portion of the mask main body expands and contracts and/or vibrates due to movement of the mouth and the chin by utterance or the like at the time of wearing the mask, so that the antibacterial effect is further improved.

In a mask main body including a piezoelectric yarn, the inventors of the present application examined, for example, a plurality of darts are formed from a central portion of the mask main body towards an edge portion of the mask main body, and the mask main body is three-dimensionally sewn (refer to, for example, a central portion C of a mask main body 101 and darts 111 and 112 in the longitudinal direction and darts 113a to 113d in the transverse direction illustrated in FIG. 1), so that the central portion of the mask main body is physically supported and fixed by the darts, and a fit feeling is improved (refer to FIG. 4 and FIG. 7).

As a result of examination, the inventors of the present application have found that the mask main body efficiently expands and contracts and/or vibrates by physically supporting the central portion of the mask main body by such darts, and that the mask main body exhibits an improved antibacterial effect.

In the present disclosure, there is provided a mask having a body that includes a yarn formed of a potential generating filament; and at least one dart that extends from an edge portion of the body towards a central portion of the body.

In the present disclosure, it is possible to obtain a mask that exhibits a further improved antibacterial effect by further efficiently expanding and contracting the mask main body in the periphery of the nose and mouth of the mask without using a drug such as an antibacterial agent and/or an antiviral agent. Note that the effects described in the present specification are merely examples and are not limited, and additional effects may be provided.

### BRIEF DESCRIPTION OF THE DRAWINGS

FIG. 1 is a schematic view schematically illustrating a first surface (front surface) of a mask according to an embodiment of the present disclosure.

FIG. 2 is a schematic exploded view schematically illustrating a configuration of the mask according to the embodiment of the present disclosure.

FIG. 3 is a schematic view schematically illustrating a second surface (back surface) of the mask according to the embodiment of the present disclosure.

FIG. 4 is a schematic view schematically illustrating a first side surface (left side surface) of the first surface (front surface) of the mask according to the embodiment of the present disclosure.

FIG. 5 is a partially exploded schematic view schematically illustrating a mask main body on the first side surface (left side surface) of the first surface (front surface) of the mask according to the embodiment of the present disclosure.

FIG. 6 is a schematic view schematically illustrating arrangement of a plurality of darts provided on the first surface (front surface) of the mask according to the embodiment of the present disclosure.

FIG. 7 is a schematic view schematically illustrating a wearing example of the mask according to the embodiment of the present disclosure.

FIG. 8 is a schematic view schematically illustrating another wearing example of the mask according to the embodiment of the present disclosure.

FIG. 9 is a schematic view schematically illustrating an auxiliary tool that can be used in the mask according to the embodiment of the present disclosure.

FIG. 10A is a diagram illustrating a configuration of a yarn 1 (S yarn), FIG. 10B is a sectional view taken along line A-A of FIG. 10A, and FIG. 10C is a sectional view taken along line B-B of FIG. 10A.

FIGS. 11A and 11B are diagrams illustrating a relationship among a uniaxial stretching direction of polylactic acid, an electric field direction, and deformation of a potential generating filament (or an electric field forming filament or a piezoelectric fiber) 10.

FIG. 12A is a diagram illustrating a configuration of a yarn 2 (Z yarn), FIG. 12B is a sectional view taken along line A-A of FIG. 12A, and FIG. 12C is a sectional view taken along line B-B of FIG. 12A.

FIG. 13 is a sectional view schematically illustrating a cross section of a yarn including a dielectric 100 around a potential generating filament 10.

FIGS. 14A to 14G illustrate a result of image analysis using ARAMIS for masks produced in Examples and Comparative Examples.

FIG. 15 is a photograph illustrating a device for measuring a surface potential of a mask main body.

FIG. 16 is a photograph illustrating a state in which the mask main body is fixed to the device for measuring the surface potential.

FIG. 17 is a schematic view schematically illustrating a sample used in an antibacterial test.

FIG. 18 is a photograph illustrating a state of an antibacterial test using the sample.

### DESCRIPTION OF THE PREFERRED EMBODIMENTS OF THE INVENTION

The present disclosure relates to a mask wherein the body of the mask includes a yarn formed of potential generating filaments and includes at least one dart disposed from an edge portion (E) of the main body towards a central portion (C) of the main body (hereinafter, it may be referred to as “mask of the present disclosure”). Hereinafter, terms used in the mask of the present disclosure will be briefly described.

In the present disclosure, the “mask” means an article or a product that covers at least the periphery of the nose and mouth of human's face to prevent dust, bacteria, and/or viruses from entering the nasal cavity and oral cavity. The mask of the present disclosure can also cover at least a part of human's cheek or chin. The mask of the present disclosure has a main body that can mainly cover human's nasal cavity and oral cavity.

In the present disclosure, the “main body” (hereinafter, it may be referred to as a “mask main body”) of the mask includes a yarn formed of potential generating filaments.

In the present disclosure, the “yarn formed of potential generating filaments” means an elongated yarn-like member including a “potential generating filament” or an “electric field forming filament” (or a fiber capable of generating a potential by a surface charge and forming an electric field) to be described in detail below. Such a yarn can form an electric field by applying external energy, for example, an external force (such as tension and/or stress or strain) in the axial direction of the yarn, and generate a positive or negative surface potential.

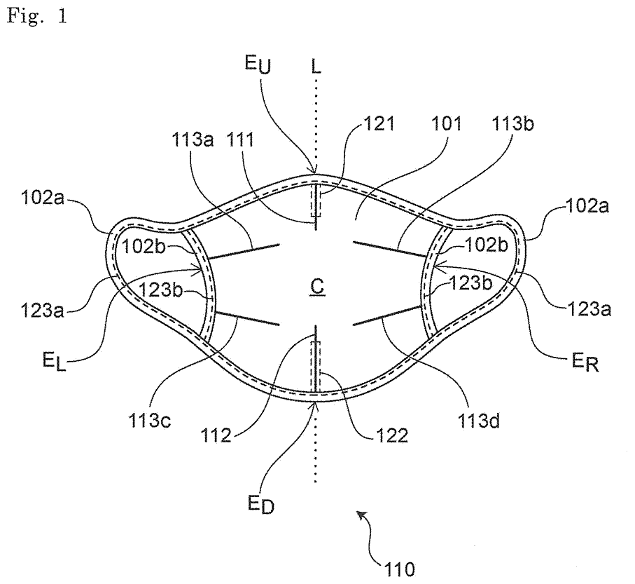

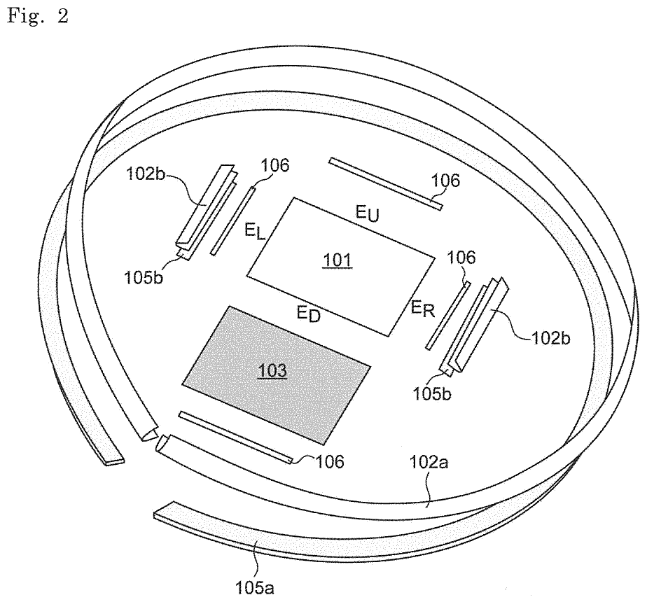

In the present disclosure, the mask main body mainly includes a “central portion” (for example, in FIGS. 1, 4, and 6, a portion indicated by a reference numeral “C”) that covers at least a part of human's the nasal cavity and/or oral cavity and an “edge portion” (for example, a portion indicated by a symbol “E” in FIGS. 1 and 2) that defines an outer shape of the mask main body.

The central portion of the mask main body may be a region including a geometric center of the mask main body and peripheral region thereof.

The mask main body is a component or member that can be formed of a sheet-like material that can be made of a yarn formed of a potential generating filament. The mask main body can be formed of, for example, a fabric such as a woven fabric, a knitted fabric, or a nonwoven fabric.

The mask of the present disclosure includes at least one dart that may be disposed from an edge portion of the mask main body towards a central portion (including the periphery thereof) of the mask main body. In other words, the mask includes at least one dart disposed from the central portion of the mask main body (including the periphery thereof) towards the edge portion of the mask main body.

In the present disclosure, the term “dart” is a term that can be generally used in the field of clothing and stitching, and means, for example, a portion or a stitched portion obtained by picking a part of the fabric from the back side and stitching the fabric at the back side in order to three-dimensionally stitch the fabric. Such darts are different from pleats and tacks in which a part of the fabric is overlapped and fixed by stitching.

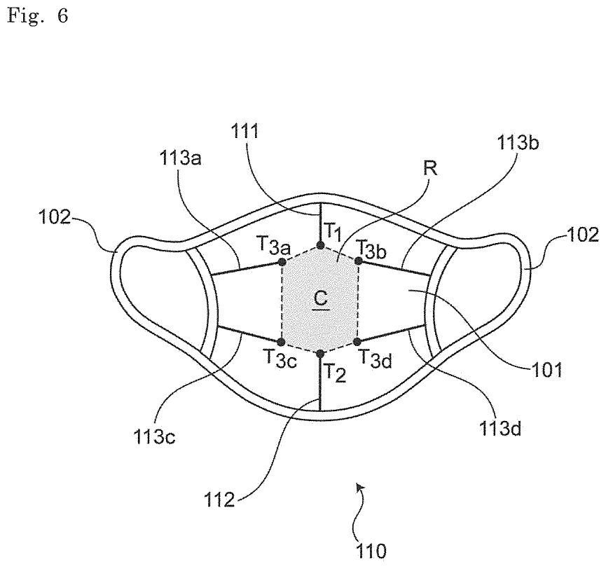

The number of darts is not particularly limited, and is, for example, 1 to 10, and preferably 2 to 6. It is preferable that the darts are disposed in pairs at vertically or horizontally symmetrical positions in the mask main body (refer to FIGS. 1 and 6).

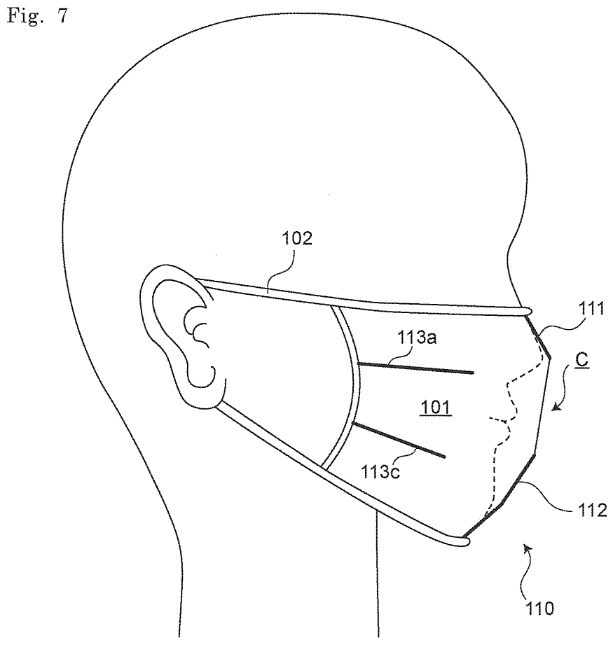

In the mask main body of the present disclosure, the mask main body can be configured more three-dimensionally by providing at least one dart. In particular, a central portion of the mask main body can be physically supported (refer to FIGS. 1 and 7). Such a dart support structure allows the mask of the present disclosure to more effectively expand and contract and/or vibrate the central portion of the mask main body in accordance with movement of the mouth, for example, during utterance (refer to, for example, the central portion indicated by reference numeral C and the region indicated by reference numeral R in FIG. 6). As a result, the yarn formed of potential generating filaments included in the mask main body is more effectively pulled by the expansion and contraction and/or vibration of the mask main body, so that more charges or potentials are generated, and a more improved antibacterial effect and the like can be exhibited.

In the main body of the mask of the present disclosure, it is preferable that such darts hardly expand and contract or do not expand and contract at all. In other words, the darts may form a non-stretchable region in the mask main body. By forming the non-stretchable region in the mask main body, the mask main body can be more reliably and three-dimensionally fixed, and stress applied to the central portion of the mask main body can be concentrated. As a result, the central portion of the mask main body can more effectively expand and contract and/or vibrate.

As described above, when the mask main body includes the darts, it is possible to more effectively expand and contract and/or vibrate the central portion of the mask main body by using the movement of human's face, more specifically, the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

A method for fixing the mask main body is not particularly limited. For example, as illustrated in FIGS. 1 and 2, a body contact member (102a) is provided at upper and lower edge portions (E_{U}, E_{D}) of the mask main body, and a ring is formed together with the body contact member (102b) provided at left and right edge portions (E_{L}, E_{R}), so that the body contact member (102a) formed in a band shape or a string shape can be hooked on the ear as an “ear hooking portion”. The mask main body can be fixed to the body by such a method (refer to FIG. 7).

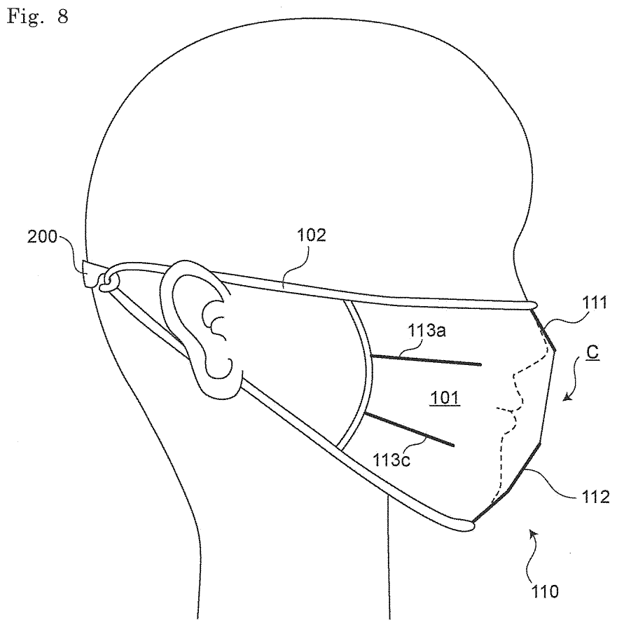

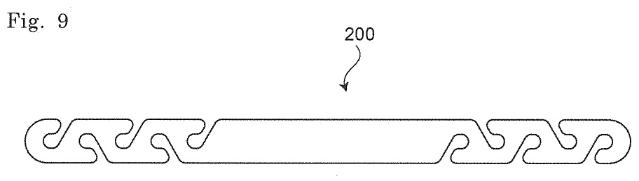

Alternatively, the body contact member (102a) can be connected and fixed to the back of the head using an auxiliary tool (200) (refer to FIG. 9) (hereinafter, it may be referred to as a “mask hook”) to be described in detail below (refer to FIG. 8). In addition, as for such a body contact member (102a), the body contact members (102a) may be directly coupled to each other at the back of the head (not shown).

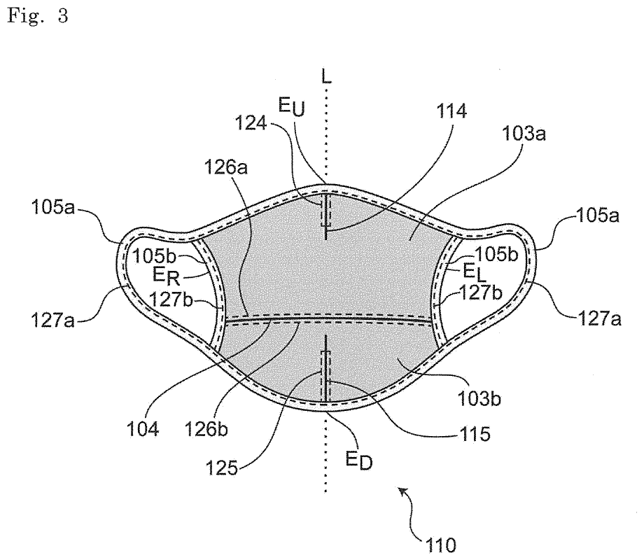

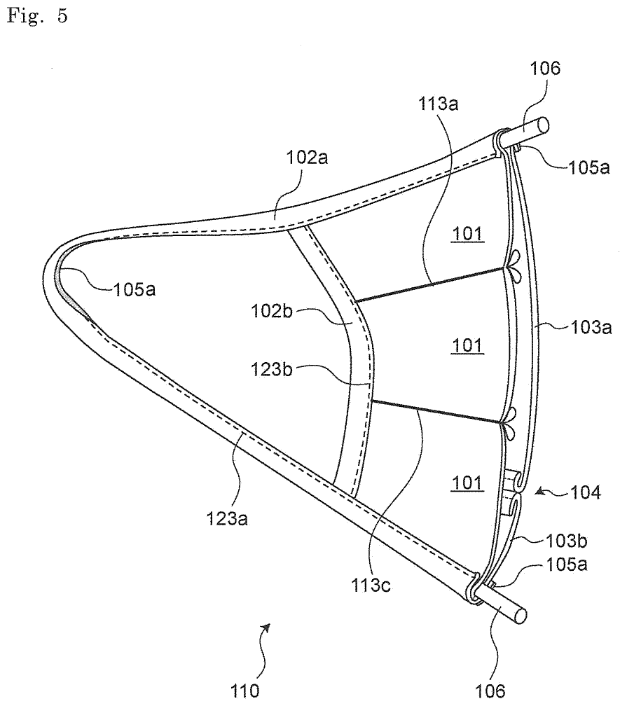

The mask of the present disclosure may further include, for example, a lining (for example, a component or member indicated by reference numeral 103 in FIGS. 2 and 3), a wire (for example, a member indicated by reference numeral 106 in FIGS. 2 and 5), a friction material (for example, a component or member indicated by reference numeral 105 in FIGS. 2 to 5), and the like as necessary.

### Embodiment

For example, FIG. 1 illustrates a mask 110 according to an embodiment of the present disclosure. A main body 101 of the mask 110 includes a yarn (hereinafter referred to as “yarn of the present disclosure” or simply “yarn”) formed of potential generating filaments. As described in detail below, the yarn of the present disclosure can generate a potential by receiving energy from the outside and receiving a tensile force in, for example, an axial direction of the yarn, and thus can exhibit an antibacterial effect and/or an antiviral effect, a dust collection effect, and the like by the generated potential.

The main body 101 may be formed of a fabric such as a woven fabric, a knitted fabric, or a nonwoven fabric including the yarn of the present disclosure. Considering the generation of a potential due to the expansion and contraction of the yarn, the mask main body 101 is preferably formed of a knitted fabric.

The main body 101 may include at least one dart, such as darts 111 and 112 in a longitudinal direction and darts 113a to 113d in the transverse direction (refer to FIG. 1). The darts 111, 112, and 113a to 113d illustrated in FIG. 1 may be arranged from edge portions (E_{U}, E_{D}, E_{L}, E_{R}) of the main body 101 towards a central portion (C) of the main body 101 (including the periphery thereof). In other words, the darts 111, 112, and 113a to 113d may be respectively arranged from the central portion (C) of the main body 101 (including the periphery thereof) towards the edge portions (E_{U}, E_{D}, E_{L}, E_{R}) of the main body 101. The darts 111, 112, and 113a to 113d may be disposed generally radially from the central portion (C) of the main body 101 (including the periphery thereof) towards the edge portions (E_{U}, E_{D}, E_{L}, E_{R}) of the main body 101.

The dart 111 is a dart that may be disposed along the ridge of the nose when the mask is worn and is hereinafter, referred to as a “first dart” or a “nose dart”.

The dart 112 is a dart that may be disposed along the chin when the mask is worn and is hereinafter, referred to as a “second dart” or a “chin dart”.

The darts 113a to 113d are darts that may be disposed along the cheek when the mask is worn and are hereinafter, referred to as “third darts” or “cheek darts”.

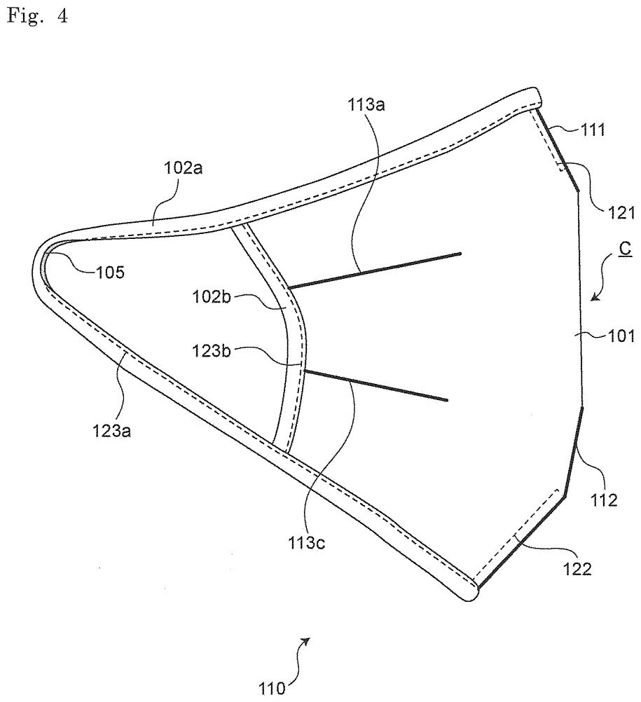

The first dart and the second dart, which can be disposed in the longitudinal direction, are sterically more effective because they can follow the ridge of the nose and the chin than the third darts, which can be disposed in the transverse direction (refer to FIG. 4).

The number of darts is not particularly limited, and for example, additional darts may be provided between the first dart 111 and the third dart 113a, between the first dart 111 and the third dart 113b, between the second dart 112 and the third dart 113c, and/or between the second dart 112 and the third dart 113d. In the mask of the present disclosure, it is preferable that the number of darts is large. This is because it reliably fits the face and improves the followability to the movement of the face.

The dimensions of the darts are not particularly limited. In the mask of the present disclosure, the size of the dart is preferably long. This is because it reliably fits the face and improves the followability to the movement of the face.

Additional third darts may be provided between the third darts 113a and 113c and between the third darts 113b and 113d.

Alternatively, a plurality of first darts 111 may be arranged in a row, or a plurality of second darts 112 may be arranged in a row.

In the mask 110, the yarn of the present disclosure can generate potentials by expanding and contracting and/or vibrating at least the central portion C (including the periphery thereof) of the main body 101. In particular, by the central portion C of the main body 101 being supported by at least one or more, preferably two or more darts, it is possible to more effectively expand and contract and/or vibrate the central portion C. In particular, it is possible to more effectively expand and contract and/or vibrate the central portion C in accordance with the movement of the mouth area and the chin at the time of utterance while the mask is worn, in other words, using the movement of the chin and the mouth at the time of utterance as the driving force. As a result, the yarn of the present disclosure including the potential generating filaments can more efficiently generate a potential to exhibit an antibacterial effect, an antiviral effect, and/or a dust-proof effect.

Furthermore, in the mask 110, the central portion C (including the periphery thereof) of the main body 101 is supported by the darts, so that, for example, breathlessness at the time of wearing can be alleviated and comfort can be exhibited.

More specifically, the main body 101 of the mask 110 preferably includes the first dart 111 which may be disposed from the edge portion E_{U} on upper side of the main body 101 towards the central portion C of the main body 101 and the second dart 112 which may be disposed from the edge portion E_{D} on the lower side of the main body 101 towards the central portion C of the main body 101. The first dart 111 and the second dart 112 may be disposed in pairs facing each other up and down, so that the central portion C of the main body 101 can be more effectively and physically supported. As described above, when the mask main body includes the darts, it is possible to more effectively expand and contract and/or vibrate the central portion C of the mask main body by using the movement of human's face, more specifically, the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

Here, the main body 101 of the mask 110 illustrated in FIG. 1 indicates a surface on a side not in contact with human's face, and is hereinafter, referred to as “first surface” or “front surface”. Also, in the present disclosure, terms such as “upper side” or simply “upper”, “lower side”, or simply “lower”, “left side”, or simply “left”, “right side”, or simply “right” refer to up, down, left, and right directions, respectively, as viewed from the “first surface” or “front surface” of the main body 101 of the mask 110. Therefore, an edge portion on the upper side of the mask 110 or the main body 101 is indicated by a reference numeral E_{U}, an edge portion on the lower side is indicated by a reference numeral E_{D}, an edge portion on the left side is indicated by a reference numeral E_{L}, and an edge portion on the right side is indicated by a reference numeral E_{R} (refer to FIGS. 1 and 2).

In the present disclosure, the vertical direction may be referred to as a longitudinal direction, and the horizontal direction may be referred to as a transverse direction.

In the mask 110, the first dart 111 and the second dart 112 may be aligned with each other along a virtual line L connecting the center (or midpoint) of the edge portion E_{U} on the upper side and the center (or midpoint) of the edge portion E_{D} on the lower side of the main body 101. Since the first dart 111 and the second dart 112 are preferably disposed along the ridge of the nose and the chin, respectively, the virtual line L can coincide with the center line of the face by the first dart 111 and the second dart 112 being aligned with each other (refer to FIG. 1). When the first dart 111 and the second dart 112 are aligned, the mask main body 101 can be disposed in close contact with the ridge of the nose and the chin in a more three-dimensional manner (refer to FIGS. 7 and 8). With such an arrangement of darts, the central portion C of the main body 101 can be supported more three-dimensionally, and the central portion C can more effectively expand and contract and/or vibrate (refer to FIG. 4). More specifically, it is possible to more effectively expand and contract and/or vibrate the central portion C of the mask main body by using the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

The main body 101 of the mask 110 may include the third darts 113 (more specifically, the darts indicated by reference numerals 113a to 113d in FIG. 1) which may be arranged from the edge portion E_{L} on the left side and/or the edge portion E_{R} on the right side of the main body 101 towards the central portion C of the main body (including the periphery thereof), in other words, towards the virtual line L. By providing the third darts, the central portion C of the main body 101 can be further three-dimensionally held (refer to FIG. 4).

The third darts 113 (more specifically, the third darts 113a to 113d) are preferably arranged along the cheek (refer to FIGS. 7 and 8). The plurality of third darts 113 (more specifically, the third darts 113a to 113d) are preferably arranged in the main body 101 in a positional relationship of vertical symmetry and/or horizontal symmetry. The central portion C of the mask main body 101 can be more stably supported by arranging the plurality of third darts in a vertical symmetrical and/or horizontal symmetrical positional relationship.

Specifically, as illustrated in FIG. 1, the third darts 113a and 113 c can be arranged in pairs symmetrically in the vertical direction, and the third darts 113a and 113b can be arranged in pairs symmetrically in the horizontal direction. In addition, the third darts 113b and 113d can be arranged vertically symmetrically in pairs, and the third darts 113c and 113d can be arranged horizontally symmetrically in pairs.

In the mask of the present disclosure, it is preferable to provide the darts in pairs in such a manner that the darts are vertically and/or horizontally symmetrical. With such a symmetrical configuration, the central portion C of the main body 101 can be physically supported more stably. Furthermore, the mask 110 can be more fitted and worn on the face (refer to FIGS. 7 and 8). In particular, since the mask can be more fitted and abut on the ridge of the nose, the chin, the cheek, and the like, the central portion C of the mask main body 101 can be more three-dimensionally supported to more effectively expand and contract and/or vibrate in accordance with the movement of the mouth at the time of utterance and the like. More specifically, it is possible to more effectively expand and contract and/or vibrate the central portion C of the mask main body by using the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

The first dart 111 and the second dart 112 and the third darts 113 are respectively arranged facing the central portion C (including the periphery thereof) of the main body (refer to FIG. 1), and the ends of the first dart 111 and the second dart 112 and the third darts 113 facing the central portion C (including the periphery thereof) of the main body 101 may be positioned spaced apart from each other (refer to, for example, ends denoted by reference numerals T₁, T₂, T₃ₐ, T_{3b}, T_{3c}, and T_{3d} in FIG. 6).

Here, the end T of the dart means one end (T) of the two ends of the dart that is oriented towards the central portion C of the main body 101 (refer to FIG. 6). The other end of the dart is generally formed at either edge portion of the main body 101 (E_{U}, E_{D}, E_{L}, E_{R}) and covered by a body contact member (102a, 102b), such as binding, piping, taping, and the like (refer to FIG. 1).

For example, the end T₁ illustrated in FIG. 6 is one end of the first dart 111, the end T₂ is one end of the second dart 112, and the ends T₃ₐ to T_{3d} are one ends of the third darts 113a to 113d.

The ends T₁ and T₂ as well as the ends T₃ₐ to T_{3d} are preferably located apart from one another, since they are intended to physically support the central portion C (including the periphery thereof) of the main body 101 (refer to FIG. 6). The separation distance between the ends is not particularly limited. In addition, the ends may overlap as necessary, or additional darts may be formed so as to connect the ends.

With such an arrangement in which the ends of the darts are separated from each other, it is possible to more effectively expand and contract and/or vibrate the central portion C of the mask main body by using the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

The yarn of the present disclosure can more efficiently generate a potential due to the expansion and contraction and/or vibration of the mask main body 101 in a region inside the respective ends T₁ and T₂ of the first dart 111 and the second dart 112 and the ends T₃ₐ to T_{3d} of the third darts 113a to 113d illustrated in FIG. 6, for example, in a region R illustrated in FIG. 6. More specifically, it is possible to more effectively expand and contract and/or vibrate the central portion C of the mask main body by using the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

The region R preferably includes the central portion C of the main body 101, and may be the same as the central portion C of the main body 101 or may overlap at least a part of the central portion C of the main body 101. The region R preferably covers at least a part of the human's nasal cavity and/or oral cavity.

The mask of the present disclosure may further include a body contact member. In the present disclosure, the “body contact member” means a member that can be coupled to the mask main body and come into contact with the body. The body contact member may be preferably coupled to and integrated with at least a portion of at least one edge portion of the mask main body. For example, as illustrated in FIG. 1, the body contact member is a part or member denoted by reference numeral 102, specifically, parts or members denoted by reference numerals 102a and 102b.

The body contact member 102 may be coupled to an edge portion E (edge portions, for example indicated by the reference numerals E_{U}, E_{D}, E_{L} and/or E_{R} in FIGS. 1 and 2) of the mask main body. More specifically, the body contact member 102a may be coupled to both the upper and lower edge portions E_{U} and E_{D} of the mask main body 101, and the two body contact members 102b may be coupled to the left and right edge portions E_{L} and E_{R} of the mask main body 101, respectively.

Here, referring to FIG. 2, the body contact member 102 can be molded and disposed by bending a band-shaped or ribbon-shaped part or member at the center, specifically, by mountain folding at the center, and such a band-shaped or ribbon-shaped member can be coupled to the edge portion (E_{U}, E_{D}, E_{L} and/or E_{R}) of the mask main body 101 by stitching. In other words, the body contact member 102 may be provided at the edge portion (E_{U}, E_{D}, E_{L}, and/or E_{R}) of the mask main body 101 by binding or piping or taping.

The body contact member 102 may be formed to expand or extend in a string shape or a band shape from the edge portion (for example, portions indicated by reference numerals E_{U}, E_{D}, E_{L}, and/or E_{R} in FIGS. 1 and 2) of the mask main body 101 and be fixed with the ear (refer to FIGS. 1 and 7).

More specifically, as illustrated in FIG. 1, for example, the body contact member 102a may expand or extend from upper and lower edge portions (E_{U}, E_{D}) of the mask main body 101, and form a ring together with the body contact members 102b provided at the left and right edge portions (E_{L}, E_{R}) as necessary, thereby forming an “ear hooking portion” (refer to FIGS. 1 and 7).

The body contact member (102a, 102b) can be hung on both ears of the wearer by having such left and right ear hooking portions. Such an ear hooking portion or an expanding portion or an extending portion can be formed, for example, by stitching a band-shaped or ribbon-shaped member illustrated in FIG. 2.

For example, in FIG. 1, a stitch that can be formed by stitching in the body contact member 102a is schematically indicated by reference numeral 123a, and a stitch that can be formed by stitching in the body contact member 102b is schematically indicated by reference numeral 123b.

As the body contact member, for example, a cloth binder tape that can be used in the field of clothing and the like can be used without particular limitation. As the body contact member, a member having elasticity is preferable. Since the body contact member has elasticity, it is possible to provide a fit feeling and comfort at the time of wearing.

The ear hooking portion may be configured as a separate body, or may be formed of a different material, for example, a rubber string.

FIG. 2 is an exploded view schematically illustrating a configuration of the mask 110 according to the embodiment of the present disclosure illustrated in FIG. 1. The mask 110 according to the embodiment of the present disclosure illustrated in FIG. 1 includes a main body 101 as a main component.

A lining 103 may be disposed on the back side of the main body 101 as necessary (refer to FIGS. 2 and 3). The lining 103 can be used without particular limitation as long as it is a fabric (for example, a woven fabric, a knitted fabric, a nonwoven fabric, and the like) having air permeability. The lining 103 is preferably a material that is gentle to the skin because it can come into contact with the skin. The lining 103 is more preferably a weakly acidic fabric (for example, a woven fabric, a knitted fabric, a nonwoven fabric, and the like) that is gentle to the skin. As the lining 103, for example, a knitted fabric manufactured by TEIJIN FRONTIER Co., Ltd. can be used. Similarly to the mask main body, the lining 103 may include a “yarn formed of potential generating filaments”.

The lining 103 is preferably sewn together with the mask main body 101. Note that the lining 103 is not an essential component in the mask of the present disclosure. The mask main body 101 may be used as a lining instead of the lining 103.

In the present disclosure, the mask main body 101 may be referred to as a “first base cloth”, and the lining 103 may be referred to as a “second base cloth”.

As illustrated in FIGS. 1 to 3, by providing the body contact member on the mask main body, it is possible to more effectively expand and contract and/or vibrate the central portion of the mask main body by using the movement of human's face, more specifically, the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

The body contact member 102a may be provided at the edge portions (E_{U}, E_{D}) on the upper and/or lower side of the main body 101 (and edge portions on the upper and/or lower side of the lining 103 as necessary). In other words, the edge portions (E_{U}, E_{D}) on the upper and/or lower side of the mask main body 101 (and the edge portions on the upper and/or lower side of the lining 103 as necessary) may be covered with a band-shaped or ribbon-shaped body contact member 102a by binding or piping or taping.

By providing such a body contact member 102a, the adhesion to the body, particularly the face, can be further improved (refer to FIG. 7). In addition, the ear hooking portion can be simultaneously formed by stitching (refer to FIGS. 1 and 7).

The body contact member 102b may be provided at the edge portions (E_{L}, E_{R}) on the left and/or right side of the main body 101 (and edge portions on the left and/or right side of the lining 103 as necessary). In other words, the edge portions (E_{L}, E_{R}) on the left and/or right side of the mask main body 101 (and the edge portions on the left and/or right side of the lining 103 as necessary) may be covered with a band-shaped or ribbon-shaped body contact member 102b by binding or piping or taping.

By providing such a body contact member 102b, the adhesion to the body, particularly the face, can be even more improved.

In the mask of the present disclosure, the body contact member is preferably provided along the entire edge portion of the main body. In other words, in the mask of the present disclosure, all the edge portions of the mask main body are preferably covered with the body contact member (refer to FIG. 1). With such a configuration, the mask can be brought into close contact with the body, and the central portion of the mask main body can more effectively expand and contract and/or vibrate. More specifically, it is possible to more effectively expand and contract and/or vibrate the central portion of the mask main body by using the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

The body contact member may have a friction material on at least a part of the surface thereof. For example, as illustrated in FIGS. 2 and 3, the friction material 105a may be provided on one bent surface of the body contact member 102a, particularly on the surface (or the back surface) on the side in contact with the body. The friction material 105b may be provided on one bent surface of the body contact member 102b, particularly on the surface (or the back surface) on the side in contact with the body. The friction material (105 a, 105b) may be stitched together with the main body 101 (and the lining 103 as necessary) after overlapping the body contact member (102a, 102b). The friction material (105 a, 105b) may be fixed to the body contact member (102a, 102b) by adhesion.

In the present disclosure, the “friction material” means a part or member that has a higher frictional force than the body contact member and can more strongly engage with the body by directly coming into contact with the body such as the skin. The friction material is preferably a band-shaped or ribbon-shaped fabric (for example, a woven fabric, a knitted fabric, a nonwoven fabric, and the like).

As the friction material, a band-shaped or ribbon-shaped fabric (for example, a woven fabric, a knitted fabric, a nonwoven fabric, and the like) containing ultrafine fibers, for example, fibers having a diameter on the order of nanometers (nm), for example, nanofibers having a diameter of 1000 nm or less, can be used. More specifically, a band-shaped or ribbon-shaped fabric (for example, a woven fabric, a knitted fabric, a nonwoven fabric, and the like) containing polyester nanofibers having a diameter of 1000 nm or less, particularly polyester nanofibers having a diameter of approximately 700 nm can be used.

As the friction material, a band-shaped or ribbon-shaped fabric (for example, a woven fabric, a knitted fabric, a nonwoven fabric, and the like) containing NANOFRONT (NANOFRONT) (registered trademark) (polyester nanofiber having a diameter of 700 nm) manufactured by TEIJIN FRONTIER Co., Ltd. which has a high frictional force and is gentle to the skin (specifically, has a soft touch and little irritation to the skin), for example, a tape, a ribbon, or the like can be preferably used. As the friction material, a commercially available anti-slip tape or the like can also be used.

As the friction material, the above-mentioned ultrafine fiber, for example, NANOFRONT manufactured by TEIJIN FRONTIER Co., Ltd., or the like may be directly woven into the body contact member. In other words, the above-mentioned ultrafine fibers may be used as a part of the fibers constituting the body contact member.

The friction material is preferably disposed on the entire portion of the body contact member in contact with the body. With such a configuration, it is possible to prevent misalignment of the mask to improve the fit feeling, and further concentrate force such as stress on the central portion of the mask main body. More specifically, it is possible to more effectively expand and contract and/or vibrate the central portion of the mask main body by using the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

For example, FIG. 3 illustrates a second surface (back surface) of the mask 110 according to the embodiment of the present disclosure. The second surface (back surface) means a surface on a side where the mask is in direct contact with the body.

For example, as illustrated in FIG. 3, the lining 103 may be divided into two portions (103a, 103b). The two portions (103a, 103b) may be coupled to each other by stitching to form a stitched portion 104. At this time, the stitched portion may be reinforced by double stitches (126a, 126b). By configuring the lining 103 with two portions (103a, 103b), the main body 101 can be supported from the back side in a more three-dimensional manner.

The lining 103 may be provided with at least one dart (114, 115) in the same manner as the mask main body 101. Hereinafter, a dart 114 is referred to as a “fourth dart” and a dart 115 is referred to as a “fifth dart”.

The fourth dart 114 is preferably provided at a position corresponding to the first dart 111 of the mask main body 101. The fifth dart 115 is preferably provided at a position corresponding to the second dart 112 of the mask main body 101.

For example, as illustrated in FIGS. 1 and 3, after the first dart 111 of the mask main body 101 and the fourth dart 114 that may be provided in the lining 103 are aligned with each other, the mask main body 101 and the lining 103 may be coupled by stitching so as to surround at least a part of the darts. Therefore, a stitch 121 illustrated in FIG. 1 and a stitch 124 illustrated in FIG. 3 are in a front and back relationship. With such a configuration, it is possible to support the central portion C of the main body 101 illustrated in FIG. 1 more three-dimensionally and physically.

Similarly, after aligning the second dart 112 of the mask main body 101 and the fifth dart 115 that may be provided in the lining 103, the mask main body 101 and the lining 103 may be coupled by stitching so as to surround at least a part of the darts. Therefore, a stitch 122 illustrated in FIG. 1 and a stitch 125 illustrated in FIG. 3 are in a front and back relationship. With such a configuration, it is possible to support the central portion C of the main body 101 illustrated in FIG. 1 more three-dimensionally and physically.

The friction material (105a, 105b) coupled by stitching can be seen on the second surface (back surface) of the mask 110 according to the embodiment of the present disclosure illustrated in FIG. 3.

The shape of the mask 110 three-dimensionally formed by stitching from the first side surface (or the left side surface) of the mask 110 according to the embodiment of the present disclosure illustrated in FIG. 4 can be confirmed. The right side surface of the mask is referred to as a “second side surface”.

The central portion C of the mask main body 101 can be supported more three-dimensionally and physically by the first dart 111, the second dart 112, the third darts 1113a and 113c, the fourth dart 114 (not shown), the fifth dart 115 (not shown), and the stitch 121 (and the stitch 124) and the stitch 122 (and the stitch 125). With such a structure, the central portion C of the mask main body 101 can more effectively expand and contract and/or vibrate, and a potential can be more effectively generated.

In the mask of the present disclosure, the body contact member may include or wrap a wire (refer to, for example, wire 106 indicated by reference numeral 106 in FIG. 5).

In the present disclosure, the “wire” means an elongated member made of, for example, metal, alloy, or resin. The wire is mainly contained or encased in the body contact member, particularly covered by the body contact member, and can maintain the shape of the mask main body, for example, at an edge portion of the mask main body.

The longitudinal dimension of the wire is not particularly limited, and may be the same length as or shorter than the edge portion of the body contact member.

It is preferable that the wire is flexible and deformable, and it is more preferable that the wire is deformed according to the shape of the body on which the body contact member abuts. By using the wire, the fit feeling of the mask is improved, and the central portion of the mask main body can be more appropriately supported to expand and contract and/or vibrate. More specifically, it is possible to more effectively expand and contract and/or vibrate the central portion of the mask main body by using the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

For example, as illustrated in FIGS. 2 and 5, the body contact member 102a may include or wrap the wire 106 along the edge portion E_{U} on the upper side of the mask main body 101. Since the wire 106 disposed along the edge portion E_{U} of the mask main body 101 and covered by the body contact member 102a can be disposed at the ridge of the nose, the wire is preferably a wire having a flat rectangular cross section. The flat wire can be deformed to follow the shape of the ridge of the nose.

By arranging the wire at the ridge of the nose, it is possible to more effectively expand and contract and/or vibrate the central portion of the mask main body by using the movement of human's face, more specifically, the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

For example, as illustrated in FIGS. 2 and 5, the body contact member 102a may include or wrap the wire 106 along the edge portion E_{D} on the lower side of the mask main body 101. Since the wire 106 disposed along the edge portion E_{D} of the mask main body 101 and covered by the body contact member 102a can be disposed at the chin, the wire is preferably a wire having a rod-shaped circular cross section.

By disposing the wire on the chin, it is possible to more effectively expand and contract and/or vibrate the central portion of the mask main body by using the movement of human's face, more specifically, the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

For example, as illustrated in FIG. 2, the body contact member 102b may include or wrap the wire 106 along the edge portions (E_{L}, E_{R}) on the left and/or right of the mask main body 101. Since the wire 106 disposed along the edge portion (E_{L}, E_{R}) of the mask main body 101 and covered by the body contact member 102b can be disposed at the cheek, the wire is preferably a wire having a rod-shaped circular cross section.

By disposing the wire on the cheek on the left side and/or the right side, it is possible to more effectively expand and contract and/or vibrate the central portion of the mask main body by using the movement of human's face, more specifically, the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

In the mask of the present disclosure, the wire is preferably disposed along at least a part of all the edge portions of the mask main body. With such a configuration including the wire, all the edge portions of the mask main body can be brought into close contact with each other according to the shape of the body, and the central portion of the mask main body can be supported more three-dimensionally and physically by fixing the mask main body.

FIG. 5 schematically illustrates a cross section of a first side surface (left side surface) of the mask 110 according to the embodiment of the present disclosure. A third base cloth may be disposed between the mask main body 101 (first base cloth) and the lining 103 (second base cloth) as necessary. The third base cloth may be a fabric (for example, woven fabric, knitted fabric, and nonwoven fabric) or the like capable of imparting cushioning property.

As illustrated in FIGS. 6 and 7, in the mask of the present disclosure, the central portion C of the mask main body 101 can be appropriately disposed in the periphery of the nasal cavity and/or the oral cavity by being hung on the ear using the body contact member 102.

In addition, the mask of the present disclosure may be configured such that the body contact member may expand or extend in a string or band shape from the edge portion of the mask main body to be disposed at the back of the head by the body contact member that may be coupled to the mask main body.

By fixing the mask at the back of the head, the mask can be more reliably worn on the face. It is possible to more effectively expand and contract and/or vibrate the central portion of the mask main body by using the movement of the face, more specifically, the movement of the chin or the mouth area at the time of utterance as a driving force. As a result, the yarn of the present disclosure including the potential generating filaments can more efficiently generate a potential to exhibit an antibacterial effect, an antiviral effect, and/or a dust-proof effect.

For example, the body contact member 102 can be disposed on the back of the head by using an auxiliary tool (or mask hook) 200 as illustrated in FIGS. 8 and 9. Here, the “back of the head” means a portion behind the ear of the human head.

As illustrated in FIG. 9, an auxiliary tool 200 is a plate flexible part or member, and can be produced by, for example, metal, alloy, or resin. The auxiliary tool 200 has several slits, which can be engaged with the ear hooking portion of the body contact member 102 by hooking the ear hooking portion on the slits (refer to FIG. 8).

By fixing the body contact member 102 at the back of the head in this manner, the mask can be more reliably disposed at the mouth area, and the vibration can be more efficiently transmitted to the central portion of the mask main body.

Alternatively, the two ear hooking portions formed on the left and right of the mask main body may be directly coupled at the back of the head without using an auxiliary tool. At this time, the two ear hooking portions may be integrated. When the two ear hooking portions are directly coupled at the back of the head, a length adjusting instrument such as a hook for adjusting the length may be disposed at any place of the extended portion of the band-shaped or string-shaped body contact member 102.

Although the mask of the present disclosure has been described in some embodiments, the mask of the present disclosure is not limited to the above embodiments.

[Yarn Formed of Potential Generating Filaments]

Hereinafter, a yarn (hereinafter, sometimes abbreviated as “yarn of the present disclosure” or simply “yarn”) that can constitute the mask main body of the present disclosure will be described in detail. Although the description will be made with reference to the drawings as necessary, various elements in the drawings are merely schematically and exemplarily shown for understanding of the present disclosure, and appearance, dimensional ratios, and the like may be different from the actual ones.

The various numerical ranges referred to herein are intended to include the lower and/or upper numerical limits themselves, unless otherwise noted, such as “less than” or “more than/greater than”. That is, when a numerical range such as 1 to 10 is taken as an example, unless otherwise specified, it can be interpreted as including not only the lower limit value “1” but also the upper limit value “10”.

Also, various numerical values may be labeled with “approximately” meaning that the terms “approximately” can include variations of a few percent, for example, less than ±10%, ±5%, ±3%, ±2%, or about ±1%.

The yarn of the present disclosure includes, for example, a plurality of “potential generating filaments” or “electric field forming filaments”. The number of the potential generating filaments or the electric field forming filaments is not particularly limited, and for example, 2 or more, 2 to 500, preferably 10 to 350, and more preferably about 20 to 200 potential generating filaments may be included in the yarn of the present disclosure.

In the present disclosure, a “potential generating filament” or an “electric field forming filament” means a fiber (or filament) capable of generating a potential by generating a charge by external energy and forming an electric field (hereinafter, it may be referred to as “charge generating fiber” or “charge generating filament” or “electric field forming fiber”).

The term “potential generating filament” can be used substantially synonymously with “electric field forming filament”.

Examples of the “energy from the outside” that the potential generating filament can be subjected to include a force from the outside such (hereinafter, it may be referred to as an “external force”), specifically a force that causes deformation or strain in the yarn or filament and/or a force applied in the axial direction of the yarn or filament, more specifically, a tension (for example, tensile force in the axial direction of the yarn or filament) and/or a stress or a strain force (tensile stress or tensile strain on the yarn or filament), and/or a force applied in the transverse direction of the yarn or filament.

The dimension (length, thickness (diameter), and the like) and the shape (cross-sectional shape and the like) of the potential generating filament are not particularly limited. The yarn of the present disclosure including such potential generating filaments may include a plurality of potential generating filaments having different thicknesses. Therefore, the yarn of the present disclosure may or may not have a constant diameter in the length direction.

The potential generating filament may be a long fiber or a short fiber. The potential generating filament may have a length (or dimension) of, for example, 0.01 mm or more, preferably 0.1 mm or more, more preferably 1 mm or more, even more preferably 10 mm or more, 20 mm or more, or 30 mm or more. The length may be appropriately selected according to a desired use. The upper limit value of the length is not particularly limited, and is, for example, 10,000 mm, 100 mm, 50 mm, or 15 mm.

The thickness of the potential generating filament, that is, the single fiber diameter is not particularly limited, and may be the same (or constant) or may not be the same along the length of the potential generating filament. The potential generating filament may have a single fiber diameter, for example, from 0.001 μm (1 nm) to 1 mm, preferably from 0.01 μm to 500 μm, more preferably from 0.1 μm to 100 μm, particularly, 1 μm to 50 μm, and for example, 10 μm or 30 μm. The single fiber diameter may be appropriately selected according to a desired use.

Furthermore, the fiber strength of the potential generating filament is preferably 1 to 10 cN/dtex. Thus, even if greater deformation occurs to generate a high potential, the potential generating filament can withstand without breaking. The fiber strength is more preferably 1 to 7 cN/dtex, most preferably 1 to 5 cN/dtex. For the same purpose, the elongation of the potential generating filament is preferably 10% to 50%.

The shape of the electric potential generating filament, in particular, cross-sectional shape is not particularly limited, and the electric potential generating filament may have, for example, a circular, elliptical, or irregular cross section. It is preferable to have a circular cross-sectional shape.

The potential generating filament preferably includes a material having a photoelectric effect, a material having a pyroelectric effect, or a material (hereinafter, it may be referred to as a “piezoelectric material” or a “piezoelectric body”) having a piezoelectric effect (polarization phenomenon by external force) or piezoelectricity (the property of generating a voltage when a mechanical strain is applied or, conversely, generating a mechanical strain when a voltage is applied). Among them, it is particularly preferable to use fibers containing a piezoelectric material (hereinafter, it may be referred to as a “piezoelectric fiber”). Since the piezoelectric fiber can form an electric field by piezoelectric, more specifically, generate a potential, a power supply is unnecessary, and there is no risk of electric shock. In addition, the life of the piezoelectric material that may be contained in the piezoelectric fiber may last longer than, for example, the antibacterial effect of a drug or the like. Such piezoelectric fibers are less likely to cause allergic reactions.

The “piezoelectric material” can be used without particular limitation as long as it is a material having a piezoelectric effect or piezoelectricity, and may be an inorganic material such as piezoelectric ceramics or an organic material such as a polymer.

The “piezoelectric material” (or “piezoelectric fiber”) preferably contains a “piezoelectric polymer”. Examples of the “piezoelectric polymer” include a “piezoelectric polymer having pyroelectricity” and a “piezoelectric polymer having no pyroelectricity”.

The “piezoelectric polymer having pyroelectricity” is generally meant a piezoelectric material formed of a polymeric material that has pyroelectricity and can generate charges (or potentials) on its surface by imparting a change in temperature. Examples of such a piezoelectric polymer include polyvinylidene fluoride (PVDF). In particular, one that can generate charges (or potentials) on the surface thereof by thermal energy of the human body is preferable.

The “piezoelectric polymer without pyroelectricity” generally means a piezoelectric polymer (hereinafter, it may be referred to as “piezoelectric polymer”) formed of a polymeric material (polymer material or resin material) and excluding the above-described “piezoelectric polymer with pyroelectricity”. Examples of such a piezoelectric polymer include polylactic acid (PLA).

As the polylactic acid (PLA), poly-L-lactic acid (PLLA) (in other words, a polymer substantially formed only of a repeating unit derived from an L-lactic acid monomer) obtained by polymerizing an L-form monomer, poly-D-lactic acid (PDLA) (in other words, a polymer substantially formed only of a repeating unit derived from a D-lactic acid monomer) obtained by polymerizing a D-form monomer, mixtures thereof, and the like are known.

As polylactic acid (PLA), copolymers of L-lactic acid and/or D-lactic acid with a compound copolymerizable with the L-lactic acid and/or D-lactic acid may be used.

A mixture of “polylactic acid (polymer formed of repeating units substantially derived from monomers selected from the group consisting of L-lactic acid and D-lactic acid)” and a “copolymer of L-lactic acid and/or D-lactic acid and compound copolymerizable with L-lactic acid and/or D-lactic acid” may be also used.

In the present disclosure, a polymer containing the above polylactic acid (PLA) is referred to as a “polylactic acid-based polymer”. In other words, the “polylactic acid-based polymer” means “polylactic acid (polymer formed of repeating units substantially derived from monomers selected from the group consisting of L-lactic acid and D-lactic acid)”, a “copolymer of L-lactic acid and/or D-lactic acid and compound copolymerizable with L-lactic acid and/or D-lactic acid”, and mixtures thereof, and the like.

Among the polylactic acid-based polymers, “polylactic acid” is particularly preferable, and it is most preferable to use a homopolymer of L-lactic acid (PLLA) and a homopolymer of D-lactic acid (PDLA).

The polylactic acid-based polymer may have a crystalline portion, or at least a part of the polymer may be crystallized. As the polylactic acid-based polymer, it is preferable to use a polylactic acid-based polymer having piezoelectricity, in other words, a piezoelectric polylactic acid-based polymer, particularly a piezoelectric polylactic acid.

In addition to the polylactic acid-based polymer, for example, polymers having optical activity, such as polypeptide-based polymers (for example, poly (γ-benzyl glutarate), poly (γ-methyl glutarate), and the like.), cellulose-based polymers (for example, cellulose acetate, cyanoethyl cellulose, and the like), polybutyric acid-based polymers (for example, poly (β-hydroxybutyric acid) or the like), and polypropylene oxide-based polymers, and derivatives thereof may be used as the piezoelectric polymer body.

The yarn of the present disclosure may have a configuration in which, as the potential generating filament (or the charge generating fiber), a conductor is used as the core yarn, an insulator is wound (covered) around the conductor, and a voltage is applied to the conductor to generate a charge or a potential.

The yarn of the present disclosure may be also a yarn obtained by simply aligning a plurality of potential generating filaments (a paralleled yarn or a non-twisted yarn), may be a twisted yarn (a stranded yarn or a twisted yarn), may be a crimped yarn (a crimped yarn or a false twisted yarn), or may be a spun yarn (a spun yarn).

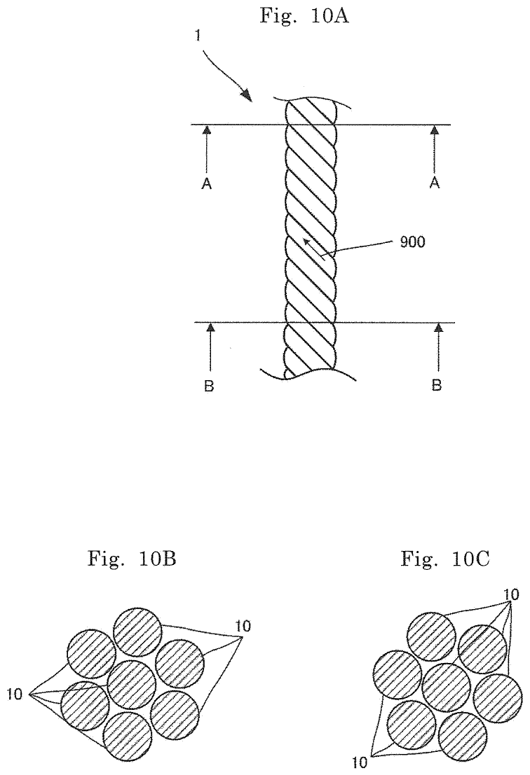

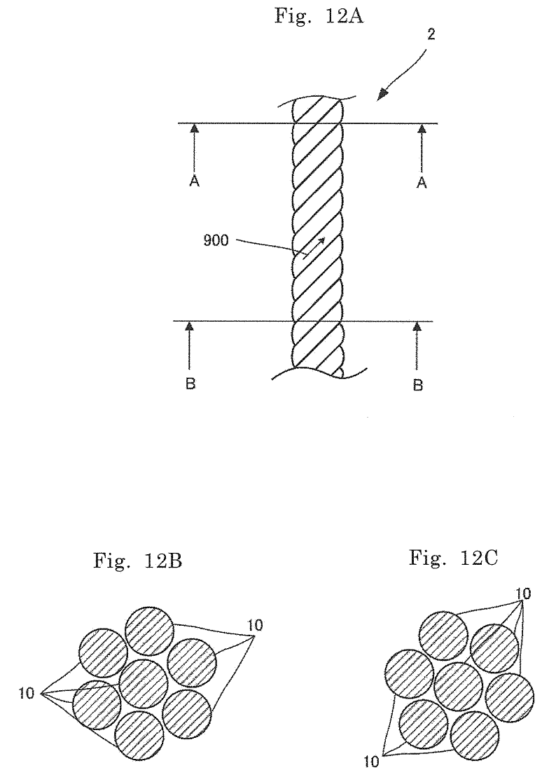

For example, as illustrated in FIG. 10A, the yarn 1 can be configured by stranding a plurality of potential generating filaments 10. In the aspect illustrated in FIG. 10A, the yarn 1 is a left-twisted yarn (hereinafter, referred to as “S yarn”) obtained by leftward twisting the potential generating filament 10, but may be a right-twisted yarn (hereinafter, referred to as “Z yarn”) obtained by rightward twisting the potential generating filament 10 (refer to, for example, yarn 2 of FIG. 12A). Thus, the yarn of the present disclosure may be either an “S yarn” or a “Z yarn” in the case of the stranded yarn.

In the yarn of the present disclosure, the distance between the potential generating filaments 10 is approximately 0 μm to approximately 10 μm, and typically about 5 μm. When the distance between the potential generating filaments 10 is 0 μm, it means that the potential generating filaments are in contact with each other.

Hereinafter, in order to describe the yarn of the present disclosure in detail, the yarn of the present disclosure will be described in more detail with reference to FIGS. 10 to 12, taking an aspect as an example, in which a piezoelectric material is included as the potential generating filament and the piezoelectric material is “polylactic acid”.

Polylactic acid (PLA) that can be used as a piezoelectric material is a chiral polymer, and has a main chain with a spiral structure. Polylactic acid can exhibit piezoelectricity when molecules are uniaxially stretched and oriented. The piezoelectric constant may be increased by further performing a heat treatment to increase the crystallinity. In other words, the “piezoelectric constant” can be increased according to the “crystallinity” (refer to “study on mechanism for developing high voltage electrical conductivity of solid-phase stretched film using polylactic acid”, Journal of the Institute of Electrostatic Engineers, 40, 1 (2016) 38-43).

The optical purity (Enantiomeric Excess (e.e.)) of polylactic acid (PLA) as a piezoelectric material is a value calculated by the following equation:

Optical purity (%)={|L-form amount−D-form amount/(L-form amount+D-form amount)}×100

For example, in both of the D-form and the L-form, the optical purity is 90 wt % or more, preferably 95 wt % or more, more preferably 98 wt % to 100 wt %, still more preferably 99.0 wt % to 100 wt %, and particularly preferably 99.0 wt % to 99.8 wt %. As the L-form amount and the D-form amount of polylactic acid (PLA), for example, values obtained by a method using high performance liquid chromatography (HPLC) can be used.

The crystallinity of polylactic acid (PLA) is, for example, 15% or more, preferably 35% or more, more preferably 50% or more, and still more preferably 55% to 100%. The crystallinity may be as high as possible, but may be, for example, 35% to 50%, and preferably 38% to 50%, from the viewpoint of the physical properties and/or dyeability of the fabric.

The crystallinity can be determined, for example, by a method using a differential scanning calorimetry (DSC) (for example, DSC7000X manufactured by Hitachi High-Tech Science Corporation), a measurement method such as X-ray diffraction (XRD) (for example, an X-ray diffraction method using ultraX 18 manufactured by Rigaku Corporation) wide angle X-ray diffraction measurement (WAXD), or the like. When the crystallinity is within the above range, the charge and potential that can be generated in the yarn can be more appropriately controlled. In the present disclosure, it has been found that the measured value of the crystallinity measured using WAXD and the measured value of the crystallinity measured using DSC are different by about 1.5 times (DSC measured value/WAXD measured value≈1.5).

As illustrated in FIG. 10A, the potential generating filament (or piezoelectric fiber) 10 containing uniaxially stretched polylactic acid has tensor components of d₁₄ and d₂₅ as piezoelectric strain constants when a thickness direction is defined as a first axis, a stretching direction 900 is defined as a third axis, and a direction orthogonal to both the first axis and the third axis is defined as a second axis.

Therefore, polylactic acid can generate charges or potential most efficiently when distortion occurs in a direction of 45 degrees with respect to the uniaxially stretched direction.

The potential generating filament of the present disclosure is preferably free of additives such as plasticizers and/or lubricants. In general, it has been found that when an additive is contained in the potential generating filament, a surface potential tends to be hardly generated. Therefore, in order to appropriately generate the surface potential, it is preferable that the potential generating filament does not contain an additive. As used herein, the “plasticizer” is a material for imparting flexibility to the potential generating filament, and the “lubricant” is a material for improving molecular slippage of the piezoelectric yarn. Specifically, polyethylene glycol, castor oil-based fatty acid ester, polyoxyethylene sorbitan fatty acid ester, polyethylene glycol fatty acid ester, stearic acid amide and/or glycerin fatty acid ester and the like are contemplated. These materials are not contained in the potential generating filament of the present disclosure.

The potential generating filament of the present disclosure may contain a hydrolysis inhibitor. In particular, a hydrolysis inhibitor for polylactic acid (PLA) may be contained. As an example of the hydrolysis inhibitor, carbodiimide may be contained. More preferably, a cyclic carbodiimide may be contained. More specifically, the cyclic carbodiimide disclosed in Japanese Patent No. 5475377 may be used. According to such a cyclic carbodiimide, the acidic group of the polymer compound can be effectively sealed. Incidentally, a carboxyl group sealing agent may be used in combination with the cyclic carbodiimide compound to such an extent that the acidic group of the polymer can be effectively sealed. Examples of the carboxyl group sealing agent include agents disclosed in JP 2005-002174 A, for example, an epoxy compound, an oxazoline compound, and/or an oxazine compound.

Hereinafter, the role of the hydrolysis inhibitor will be described. A generally known filament containing PLA (a filament that does not generate a surface potential) in the related art generates an acid by hydrolysis of PLA, and the acid acts on bacteria to exhibit an antibacterial effect. Therefore, when hydrolysis occurs in the PLA, the filament is deteriorated. However, since the potential generating filament of the present disclosure has an antibacterial mechanism different from the known one and exhibits an antibacterial effect by generating a surface potential as described above, it is not necessary to cause hydrolysis. Furthermore, since the potential generating filament of the present disclosure contains a hydrolysis inhibitor, it is possible to prevent hydrolysis from occurring in the filament and to suppress deterioration of the filament.

The number average molecular weight (Mn) of the polylactic acid is, for example, 6.2×10⁴, and the weight average molecular weight (Mw) is, for example, 1.5×10⁵. The molecular weight is not limited to these values.

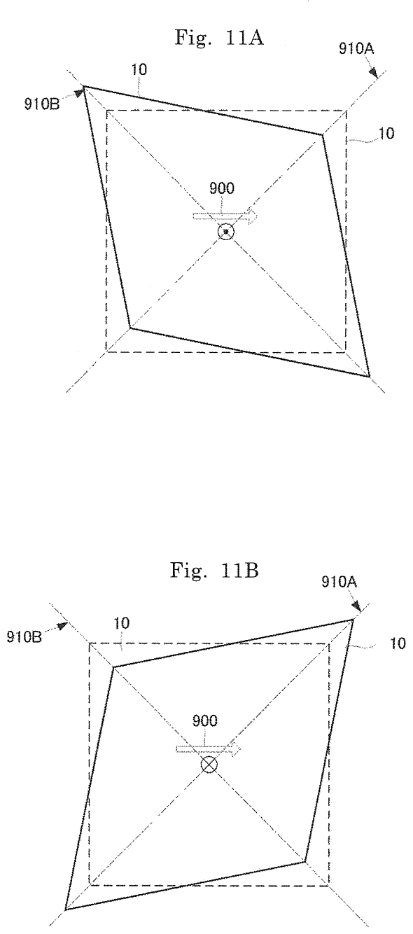

FIGS. 11A and 11B are diagrams illustrating a relationship among a uniaxial stretching direction of polylactic acid, an electric field direction, and deformation of the potential generating filament (or piezoelectric fiber) 10.

As illustrated in FIG. 11A, when the filament 10 contracts in the direction of the first diagonal line 910A and extends in the direction of the second diagonal line 910B orthogonal to the first diagonal line 910A, an electric field can be generated in a direction from the back side to the front side of the paper surface. That is, the filament 10 can generate a negative charge or potential on the front side of the paper surface. As illustrated in FIG. 11B, the filament 10 can generate a charge even when extending in the direction of the first diagonal line 910A and contracting in the direction of the second diagonal line 910B, but the polarity is reversed, and an electric field can be generated in a direction from the surface to the back side of the paper surface. That is, the filament 10 can generate a positive charge or potential on the front side of the paper surface.

Polylactic acid may have piezoelectricity due to a molecular orientation treatment by stretching, crystallinity, and the like and thus does not need to be subjected to a poling treatment unlike other piezoelectric polymers such as polyvinylidene fluoride (PVDF) or piezoelectric ceramics. The piezoelectric constant of uniaxially stretched polylactic acid is about 5 to 30 pC/N, and has a very high piezoelectric constant among polymers. Furthermore, the piezoelectric constant of polylactic acid does not vary with time and is extremely stable.

The potential generating filament 10 is preferably a fiber having a circular cross section. The potential generating filament 10 can be manufactured by, for example, a method in which a piezoelectric polymer is extruded and molded into a fiber, a method in which a piezoelectric polymer is melt-spun into a fiber (examples thereof include a spinning/stretching method in which a spinning step and a stretching step are separately performed, a straight stretching method in which a spinning step and a stretching step are connected, a POY-DTY method in which a false twisting step can also be performed at the same time, and an ultrahigh speed spinning method in which speed is increased), a method in which a piezoelectric polymer is formed into a fiber by dry or wet spinning (examples thereof include a phase separation method or a dry-wet spinning method in which a polymer as a raw material is dissolved in a solvent and extruded from a nozzle to form fibers, a gel spinning method in which fibers are uniformly formed into a gel while containing a solvent, and a liquid crystal spinning method in which fibers are formed using a liquid crystal solution or a melt), a method in which a piezoelectric polymer is formed into a fiber by electrostatic spinning, or the like. The cross-sectional shape of the potential generating filament 10 is not limited to a circular shape.

For example, the yarn 1 illustrated in FIG. 10 may be a yarn (multifilament yarn) (S yarn) obtained by twisting a plurality of potential generating filaments 10 containing such polylactic acid. The number of filaments 10 constituting the yarn 1 is not particularly limited. The stretching direction 900 of each potential generating filament 10 coincides with the axial direction of the respective potential generating filaments 10. Therefore, the stretching direction 900 of the potential generating filament 10 is inclined to the left with respect to the axial direction of the yarn 1. The angle may depend on the number of twists.

When tension is applied to the yarn 1, which is such a S yarn, a negative (−) charge or potential is generated on the surface of the yarn 1, and a positive (+) charge or potential can be generated on the inner side thereof.

The yarn 1 can form an electric field by a potential difference that can be generated by the electric charge. This electric field can also leak into a space in the vicinity to form a coupled electric field with other portions. Furthermore, the potential that may be generated in the yarn 1 can also generate an electric field between the yarn 1 and an object when brought close to the object having a nearby predetermined potential, for example, a predetermined potential (including a ground potential) such as a human body.

Next, referring to FIG. 12, since the yarn 2 is a Z yarn, the stretching direction 900 of the potential generating filament (or piezoelectric fiber) 10 is inclined to the right with respect to the axial direction of the yarn 2. The angle may depend on the number of twists of the yarn. Further, the number of filaments 10 constituting the yarn 2 is also not particularly limited.

When tension is applied to yarn 2 which is Z yarn, positive (+) charge or potential is generated on the surface of the yarn 2, and a negative (−) charge or potential can be generated on the inner side thereof.

The yarn 2 can also form an electric field by a potential difference that can be generated by the electric charge. This electric field can also leak into a space in the vicinity to form a coupled electric field with other portions. Furthermore, the potential that may be generated in the yarn 2 can also generate an electric field between the yarn 2 and an object when brought close to the object having a nearby predetermined potential, for example, a predetermined potential (including a ground potential) such as a human body.

Furthermore, when the yarn 1 that is the S yarn and the yarn 2 that is the Z yarn are brought close to each other, an electric field or potential can be generated between the yarn 1 and the yarn 2.

The polarities of charges or potentials that may be generated in the yarn 1 and the yarn 2 are different from each other. The potential difference at each position can be defined by an electric field coupling circuit that can be formed by intricately entangling fibers, or a circuit that can be formed by a current path that can be accidentally formed in the yarn with moisture or the like.

In the yarn of the present disclosure, the electric field forming filament is preferably formed of polylactic acid (PLA). When the electric field forming filament contains a piezoelectric material such as polylactic acid, the surface potential can be more appropriately controlled. In addition, since the polylactic acid is hydrophobic, it is possible to provide a smooth touch to the mask main body and to impart comfort to the mask.

The crystallinity of polylactic acid (PLA) is preferably within a range of 15% to 80%. Within such a range, the piezoelectricity derived from the polylactic acid crystal is increased, and polarization due to the piezoelectricity of the polylactic acid can be more effectively generated.

The yarns of the present disclosure should not be construed as limited to the above aspects. The method for manufacturing the yarn of the present disclosure is also not particularly limited, and is not limited to the above manufacturing method.

Furthermore, the yarns of the present disclosure may be provided with a “dielectric” around at least a portion of the potential generating filament, for example at least a portion of the longitudinal axial and/or circumferential surface of the filament.

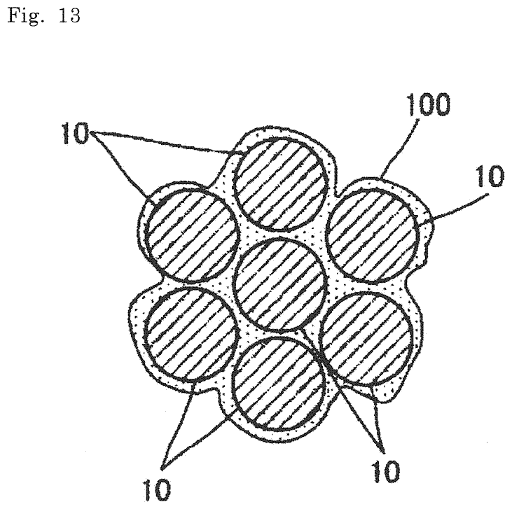

For example, as schematically illustrated in the sectional view of FIG. 13, a dielectric 100 may be provided around the potential generating filament (or piezoelectric fiber) 10.

In the yarn of the present disclosure, the “dielectric” is an optional configuration, and is not an essential configuration of the invention.

In the present disclosure, the “dielectric” means a material or a substance containing a material or a substance having dielectric properties (a property of being electrically polarized by an electric field) and/or electrical conductivity (a property of passing electricity), and for example, a charge can be accumulated on a surface thereof.

The dielectric may be present in the longitudinal axis direction and/or the circumferential direction of the potential generating filament, and may completely or partially cover the potential generating filament.

Therefore, the dielectric may be also provided entirely or partially in the longitudinal axis direction of the potential generating filament. In addition/alternatively, the dielectric may be also provided entirely or partially in the circumferential direction of the potential generating filament.

In addition, the dielectric may have a uniform or non-uniform thickness (refer to, for example, FIG. 13). The thickness of the dielectric may be larger or smaller than the fiber diameter of the potential generating filament. The thickness of the dielectric is preferably smaller than the fiber diameter of the potential generating filament (refer to FIG. 13).

The dielectric may be provided in layers on at least a part of a surface of the yarn or the potential generating filament of the present disclosure, on at least a part of a surface of the yarn or the potential generating filament of the present disclosure, for example, in a cross-sectional view or a radial cross-section of the potential generating filament. The dielectric may be present also between the plurality of potential generating filaments, and in this case, there may be portions where no dielectric is present between the plurality of potential generating filaments. In addition, bubbles or cavities may be present in the dielectric.

The dielectric is not particularly limited as long as the dielectric includes a material or a substance having dielectric properties and/or conductivity. As the dielectric, a dielectric material (for example, an oil agent, an antistatic agent, and the like) known to be able to be used mainly as a surface treatment agent (or a fiber treatment agent) in the fiber industry may be used.

In the yarn of the present disclosure, the dielectric preferably contains an oil agent. As the oil agent, an oil agent used as a surface treatment agent (or a fiber treatment agent) that can be used in the production step of the potential generating filament can be used. In addition, an oil agent that may be used as a surface treatment agent (or fiber treatment agent) that can be used in the step of manufacturing cloth (for example, knitting, weaving, and the like), and an oil agent that may be used as a surface treatment agent (or fiber treatment agent) that can be used in the finishing step can also be used. Here, as a representative example, a filament production step, a cloth production step, and a finishing step have been described, but the present invention is not limited to these steps. As the oil agent, it is preferable to use a surface treatment agent (or a fiber treatment agent) such as an oil agent that may be used particularly for reducing friction of the potential generating filament.

Examples of the oil agent include DELION series manufactured by TAKEMOTO OIL & FAT CO., LTD., MARPOZOL series and MARPOZIES series manufactured by Matsumoto Yushi-Seiyaku Co., Ltd., and PARATEX series manufactured by MARUBISHI OIL CHEMICAL CO., LTD.

The oil agent may be present entirely or at least partially along the potential generating filament. In addition, after the potential generating filament is processed into a yarn, at a part or all of the oil agents may fall off from the potential generating filament by washing.

In addition, the dielectric that may be used for reducing friction of the potential generating filament may be a surfactant such as a detergent or a softener that may be used during washing.

Examples of the detergent include ATTACK (registered trademark) series manufactured by Kao Corporation, TOP (registered trademark) series manufactured by Lion Corporation, and ARIEL (registered trademark) series manufactured by The P&G Japan Limited.

Examples of the softener include HAMMING (registered trademark) series manufactured by Kao Corporation, SOFLAN (registered trademark) series manufactured by Lion Corporation, and LENORE (registered trademark) series manufactured by The P&G Japan Limited.

The dielectric may have conductivity (property of passing electricity), and in this case, the dielectric preferably contains an antistatic agent. As the antistatic agent, an antistatic agent that may be used as a surface treatment agent (or a fiber treatment agent) that may be used in the production of the potential generating filament can be used. As the antistatic agent, it is preferable to use an antistatic agent that may be used particularly for reducing the loosening of the potential generating filament.

Examples of the antistatic agent include CAPRON series manufactured by NISSIN KAGAKU KENKYUSHO CO., LTD., NICEPOLE series and DEATRON series manufactured by NICCA CHEMICAL CO., LTD., and the like.

As the antistatic agent, a surface treatment agent (or fiber treatment agent) capable of imparting water absorbency and/or SR property (soil removability) together with an antistatic effect may be used.

The antistatic agent may be present entirely or at least partially along the potential generating filament, for example, on the surface of the potential generating filament in the longitudinal axis direction and/or the circumferential direction. In addition, after the potential generating filament is processed into a yarn, a part or all of the antistatic agents may fall off from the potential generating filament by washing.

The adhesion amount of a surface treatment agent (or a fiber treatment agent) such as an oil agent or an antistatic agent, a detergent, a softener, and the like to the potential generating filament is not particularly limited.

When the dielectric is a surface treatment agent (or fiber treatment agent) such as an oil agent or an antistatic agent, a detergent, a softener, or the like, the adhesion amount of the dielectric to the potential generating filament is, for example, 1 wt % to 20 wt %, preferably 1 wt % to 15 wt %, and more preferably 1 wt % to 5 wt %, with respect to 100 wt % of the potential generating filament.

In addition, a surface treatment agent (or a fiber treatment agent) such as the above-described oil agent or antistatic agent, a detergent, a softener, and the like may not be present around the potential generating filament. That is, the potential generating filament and thus the yarn of the present disclosure may not contain a surface treatment agent or the like. In that case, air that may be present between or in gaps between the potential generating filaments and/or around the filaments may function as a dielectric. Thus, in this case, the dielectric includes air or an air layer.

In the present disclosure, when a surface treatment agent (or a fiber treatment agent) such as an oil agent or an antistatic agent, a detergent and/or a softener, and the like described above are not present around the potential generating filament, in other words, when only an air layer is present around the filament, the presence of an extremely small amount of component that may be unavoidably or incidentally mixed during the production of the yarn or the filament can be permitted.

Yarns containing no surface treatment agent (or fiber treatment agent), detergent, softener, or the like may be used by treating yarns with the surface treatment agent (or fiber treatment agent) such as the above-described oil agent or antistatic agent, detergent, softener, or the like attached around the electric field forming filament by washing or solvent immersion. In that case, the pure electric field forming filament will be exposed. Alternatively, in the present disclosure, a yarn containing only a pure electric field forming filament may be used.

Furthermore, in the present disclosure, for example, a yarn in which a surface treatment agent (or fiber treatment agent) such as the above-described oil agent or antistatic agent, detergent, softener, and the like are partially removed by a treatment such as washing or solvent immersion, and a pure electric field forming filament is partially exposed may be used.

The thickness of the dielectric (or the distance between the potential generating filaments) is approximately 0 μm to approximately 10 μm, preferably approximately 0.5 μm to approximately 10 μm, more preferably approximately 2.0 μm to approximately 10 μm, and typically about 5 μm.

(Surface Potential)

In the yarn of the present disclosure, the surface potential generated by the application of the external force is, for example, more than 0.1 V, preferably 0.5 V or more (both positive and negative potentials can be generated). When the surface potential is larger than 0.1 V, in the mask of the present disclosure, an effect such as an antibacterial action and/or an antiviral action can be exhibited by the generated potential together with the dust collecting force (in the present disclosure, it may be collectively referred to as “antibacterial effect”). Here, the method for measuring the surface potential is not particularly limited, and the surface potential can be measured using, for example, a scanning probe microscope (EFM).

The antibacterial action and/or the antiviral action may be a direct bactericidal action and/or a virucidal action or the like by surface potential, or may be an action or the like caused by generating a potential opposite to the potential of bacteria and/or viruses such as bacteria and fungi so as not to attract bacteria and/or viruses.

Hereinafter, a mask according to an embodiment of the present disclosure will be described in detail with reference to Examples and Comparative Examples.

### EXAMPLES

### Example 1

A fabric having a smooth structure (structure that can be formed by smooth knitting) was knitted with a double 28 G knitting machine (LPJ manufactured by Precision Fukuhara Works, Ltd.) using PLLA84T72DTY (number of filaments: 72, filament diameter: 11 μm, diameter of yarn: 92 mm, optical purity of PLLA (L-form): 99% or more, crystallinity: 35% to 40%) as a yarn (piezoelectric yarn) including a potential generating filament, and the fabric was subjected to post-processing to produce a cloth including a piezoelectric yarn.

A cloth containing piezoelectric yarns was cut to form a first dart (111), a second dart (112), and third darts (113a to 113d) by stitching as illustrated in FIG. 1.

A round wire having a length of 5 cm was disposed along edge portions (E_{L}, E_{R}) on the left and right sides of the mask main body, and then a binder tape (manufactured by INOUE RIBBON INDUSTRY Co., Ltd., 1764, width: 7.5 mm) having a band shape was disposed in a mountain fold as a body contact member from the upper side thereof and fixed by stitching. Note that a tape of NANOFRONT (registered trademark) manufactured by TEIJIN FRONTIER Co., Ltd. is simultaneously stitched as a friction material into a surface (back surface) of the binder tape on a side in contact with the body.

A flat wire having a length of 12 cm was disposed along an edge portion (E_{U}) on the upper side of the mask main body, and a binder tape (BTH, width: 3 mm, obtained from Shimada Corporation) was disposed in a mountain fold from the upper side thereof and fixed by stitching. Note that a tape of NANOFRONT (registered trademark) manufactured by TEIJIN FRONTIER Co., Ltd. is simultaneously stitched as a friction material into a surface (back surface) of the binder tape on a side in contact with the body.

The binder tape provided along the edge portion (E_{U}) on the upper side of the mask main body extends from each of the edge portions (E_{L}, E_{R}) on the left and right sides of the mask main body and is coupled to each other to form a ring, so that the binder tape can be disposed and fixed on the back of the head at the time of wearing. Such a portion is formed by stitching a binder tape in a mountain folded state. A tape of NANOFRONT (registered trademark) manufactured by TEIJIN FRONTIER Co., Ltd. is simultaneously stitched as a friction material into a surface (back surface) of the binder tape on a side in contact with the body.

A binder tape on which a round wire (Cordon Co., Ltd., FK-3008, wire diameter: 3 mm) having a length of 10 cm was disposed from the upper side along an edge portion (E_{D}) on the lower side of the mask main body was disposed in a mountain fold and fixed by stitching. Note that a tape of NANOFRONT manufactured by TEIJIN FRONTIER Co., Ltd. is simultaneously stitched as a friction material into a surface (back surface) of the binder tape on a side in contact with the body.

Note that the binder tape provided along the edge portion (E_{D}) on the lower side of the mask main body is configured to extend from each of the edge portions (E_{L}, E_{R}) on the left and right sides of the mask main body and be coupled to each other to form a ring, so that the binder tape can be disposed and fixed to the back of the head at the time of wearing. Such a portion is formed by stitching a binder tape in a mountain folded state. A tape of NANOFRONT (registered trademark) manufactured by TEIJIN FRONTIER Co., Ltd. is simultaneously stitched as a friction material into a surface (back surface) of the binder tape on a side in contact with the body.

In this way, in Example 1, a mask fixed to the back of the head was produced.

### Example 2

A fabric having a smooth structure (structure that can be formed by smooth knitting) was knitted with a double 28 G knitting machine (LPJ manufactured by Precision Fukuhara Works, Ltd.) using PLLA84T72DTY (number of filaments: 72, filament diameter: 11 μm, diameter of yarn: 92 mm, optical purity of PLLA (L-form): 99% or more, crystallinity: 35% to 40%) as a yarn (piezoelectric yarn) including a potential generating filament, and the fabric was subjected to post-processing to produce a cloth including a piezoelectric yarn.

A cloth containing piezoelectric yarns was cut to form a first dart (111), a second dart (112), and third darts (113a to 113d) by stitching as illustrated in FIG. 1.

A round wire having a length of 5 cm was disposed along edge portions (E_{L}, E_{R}) on the left and right sides of the mask main body, and then a binder tape (manufactured by INOUE RIBBON INDUSTRY Co., Ltd., 1764, width: 7.5 mm) having a band shape was disposed in a mountain fold as a body contact member from the upper side thereof and fixed by stitching. Note that a tape of NANOFRONT (registered trademark) manufactured by TEIJIN FRONTIER Co., Ltd. is simultaneously stitched as a friction material into a surface (back surface) of the binder tape on a side in contact with the body.

A flat wire having a length of 12 cm was disposed along an edge portion (E_{U}) on the upper side of the mask main body, and a binder tape (BTH, width: 3 mm, obtained from Shimada Corporation) was disposed in a mountain fold from the upper side thereof and fixed by stitching. Note that a tape of NANOFRONT (registered trademark) manufactured by TEIJIN FRONTIER Co., Ltd. is simultaneously stitched as a friction material into a surface (back surface) of the binder tape on a side in contact with the body. A binder tape on which a round wire (Cordon Co., Ltd., FK-3008, wire diameter: 3 mm) having a length of 10 cm was disposed from the upper side along an edge portion (E_{D}) on the lower side of the mask main body was disposed in a mountain fold and fixed by stitching. Note that a tape of NANOFRONT manufactured by TEIJIN FRONTIER Co., Ltd. is simultaneously stitched as a friction material into a surface (back surface) of the binder tape on a side in contact with the body.

As illustrated in FIGS. 1 and 7, the binder tape provided along the edge portion (E_{U}) on the upper side of the mask main body and the binder tape provided along the edge portion (E_{D}) on the lower side of the mask main body extend from the edge portion (E_{L}) on the left side of the mask main body and are coupled to each other to form a ring, so that the binder tapes are disposed on the ear at the time of wearing. Similarly, two upper and lower binder tapes extend from the edge portion (E_{R}) on the right side of the mask main body and are coupled to each other to form a ring, so that the upper and lower binder tapes are disposed on the ear at the time of wearing (refer to FIG. 1). Such a portion is formed by stitching a binder tape in a mountain folded state. Note that a tape of NANOFRONT (registered trademark) manufactured by TEIJIN FRONTIER Co., Ltd. is simultaneously stitched as a friction material into a surface (back surface) of the binder tape on a side in contact with the body.

In this way, in Example 2, an ear fixing type mask was produced.

### Example 3

A mask fixed to the back of the head was produced in the same manner as in Example 1 except that no wire was provided at the edge portion (E_{D}) on the lower side and the edge portions (E_{L}, E_{R}) on the left and right sides of the mask main body.

### Example 4

An ear fixing type mask was produced in the same manner as in Example 2 except that no wire was provided at the edge portion (E_{D}) on the lower side and the edge portions (E_{L}, E_{R}) on the left and right sides of the mask main body.

### Example 5

An ear fixing type mask was prepared in the same manner as in Example 2 except that the third darts (113a to 113d) were not provided and wires were not provided at the edge portions (E_{U}, E_{D}) on the upper and lower sides and the edge portions (E_{L}, E_{R}) on the left and right sides of the mask main body.

### Example 6

An ear fixing type mask was prepared in the same manner as in Example 2 except that the first dart (111) and the second dart (112) were not provided and wires were not provided at the edge portions (E_{U}, E_{D}) on the upper and lower sides and the edge portions (E_{L}, E_{R}) on the left and right sides of the mask main body.

### Comparative Example 1

An ear fixing type mask was prepared in the same manner as in Example 2 except that the first dart (111), the second dart (112), and the third darts (113a to 113d) were not provided and wires and friction materials were not provided at the edge portions (E_{U}, E_{D}) on the upper and lower sides and the edge portions (E_{L}, E_{R}) on the left and right sides of the mask main body.

The configurations of the masks produced in Examples and Comparative Examples are shown in Table 1 below.

TABLE 1

| | | | | | | | | Comparative |
|---|---|---|---|---|---|---|---|---|
| | | Example | | | | | | Example |
| | | 1 | 2 | 3 | 4 | 5 | 6 | 1 |
| Darts | First (nose) | ◯ | ◯ | ◯ | ◯ | ◯ | — | — |
| | Second (chin) | ◯ | ◯ | ◯ | ◯ | ◯ | — | — |
| | Third (cheek) | ◯ | ◯ | ◯ | ◯ | — | ◯ | — |
| Friction material | | ◯ | ◯ | ◯ | ◯ | ◯ | ◯ | — |
| Wire | Upper side (nose) | ◯ | ◯ | ◯ | ◯ | — | — | — |
| | Lower side (chin) | ◯ | ◯ | — | — | — | — | — |
| | Left and right | ◯ | ◯ | — | — | — | — | — |
| | (cheek) | | | | | | | |
| Fix | Back of head | ◯ | — | ◯ | — | — | — | — |
| | Ear | — | ◯ | — | ◯ | ◯ | ◯ | ◯ |

Evaluation

| | | | | | | | |
|---|---|---|---|---|---|---|---|
| Elongation rate (average) | 4 | 3 | 4 | 3 | 3 | 3 | 0.5 |
| (%) | | | | | | | |
| Elongation rate | 8 | 6 | 7 | 6 | 5.5 | 5 | 1 |
| (maximum) (%) | | | | | | | |
| Generated potential | 0.9 | 0.6 | 0.8 | 0.6 | 0.6 | 0.5 | 0.1 |
| (V) | | | | | | | |
| Antibacterial test result | 2.8 | 2.2 | 2.4 | 2.2 | 2.1 | 2.0 | 0.5 |
| (Difference between | | | | | | | |
| numbers of bacteria) | | | | | | | |

Measurement of Elongation Rate

For the masks produced in Examples and Comparative Examples, the elongation rate in the mouth peripheral portion at the time of utterance was calculated using a non-contact optical three-dimensional strain measuring system (3D system solution “ARAMIS” manufactured by GOM).

ARAMIS is a measurement system using image analysis, and measurement was performed under the following conditions.

Subject: Male in his 40s

Malar arch width: 152 mm

Morphological face height: 112 mm

(Measurement Conditions)

Number of pixels: 12 M pixels

Measurement range: 270 mm×210 mm

Distance between points: about 1.5 mm

The average value and the maximum value of the elongation rates measured at the mouth peripheral portion (the central portion (C) of the mask and the periphery thereof) of the mask when the elongation rate of the silent state after wearing the mask is set to zero and the sound “A” is emitted are shown in Table 1.

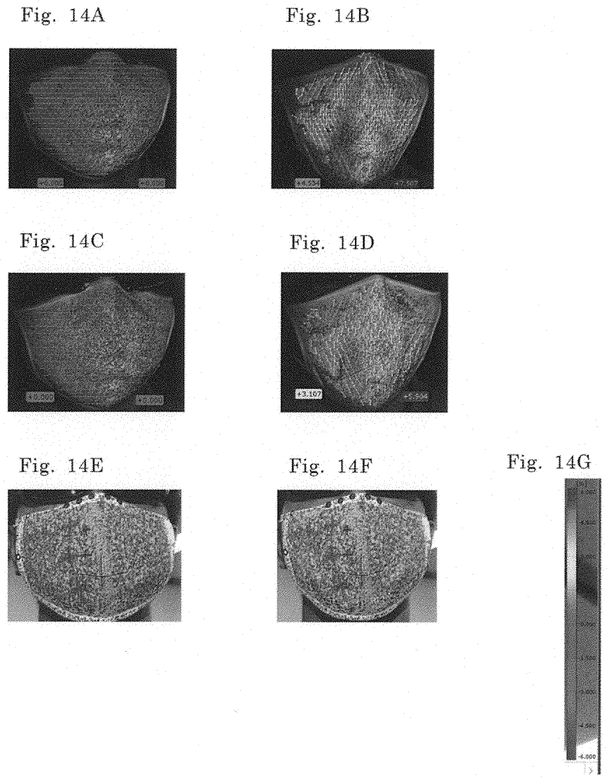

The results of image analysis using ARAMIS are illustrated in FIG. 14.

FIG. 14A illustrates Example 1 (silent state), FIG. 14B illustrates Example 1 (when sound “A” is emitted), FIG. 14C illustrates Example 2 (silent state), FIG. 14D illustrates Example 2 (when sound “A” is emitted), FIG. 14E illustrates Comparative Example 1 (silent state), FIG. 14F illustrates Comparative Example 1 (when sound “A” is emitted), and FIG. 14G illustrates color bars of the respective contour diagrams of A to F.

From the results of the elongation rate shown in Table 1, it was found that the mask of Examples 1 to 6 of the present disclosure had an elongation rate of 5 times to 8 times as compared with the mask having the known shape (Comparative Example 1).

Measurement of Generated Potential

For the masks produced in Examples and Comparative Examples, the results of measuring the surface potential that can be generated in the main body portion of the mask at the maximum elongation rate are respectively shown in Table 1.

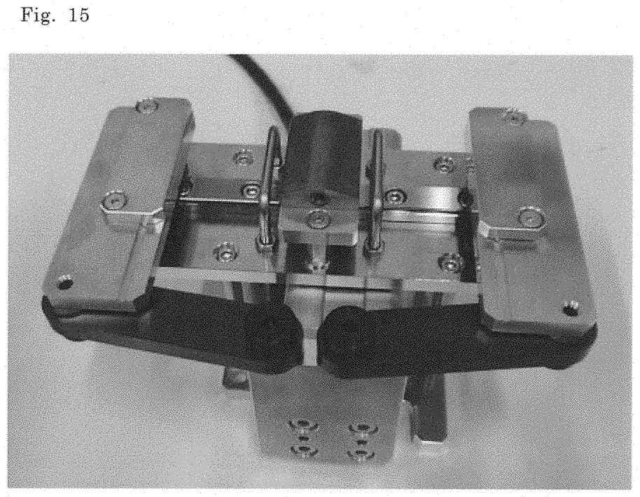

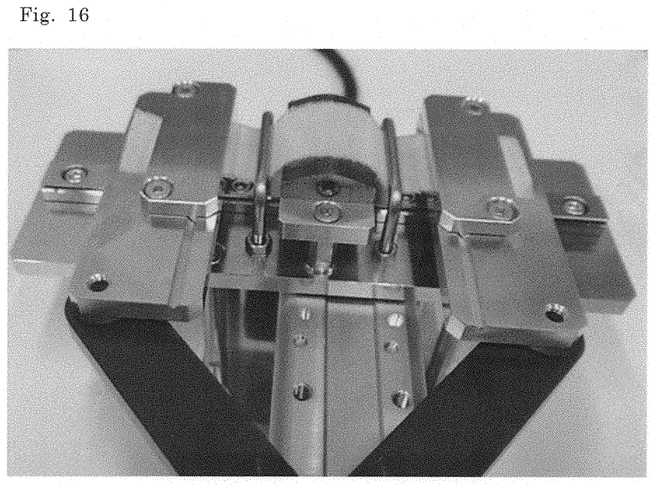

Using a device illustrated in FIG. 15, a main body portion (sample) of the mask was disposed on a block made of copper as illustrated in FIG. 16, and both end portions were fixed. GND was formed from a copper block, and the surface potential that could be generated on the surface of the mask main body when the mask main body was pulled at the maximum elongation rate shown in Table 1 from both sides of the mask main body at a displacement speed of 20 mm/sec was measured. The surface potential was measured using a cantilever provided with a probe of an electric force microscope (EFM) (Model 1100 TN manufactured by TRECH Inc.).

The measured surface potential (V) is shown in Table 1. From the results of the generated potentials shown in Table 1, it was found that the mask of Examples 1 to 6 of the present disclosure indicated the surface potential of 5 times to 9 times as compared with the mask having the known shape (Comparative Example 1).

Antibacterial Test

For each of the masks produced in Examples and Comparative Examples, a sample for an antibacterial test was prepared, the number of bacteria (the number of colonies) when the mask was inoculated with a bacterial liquid (10⁶ CFU/mL) and then repeatedly expanded and contracted for 18 hours and the number of bacteria (the number of colonies) when the mask was allowed to stand for 18 hours were counted respectively, and then the difference between the numbers of bacteria is shown as an antibacterial test result in Table 1.

(Sample)

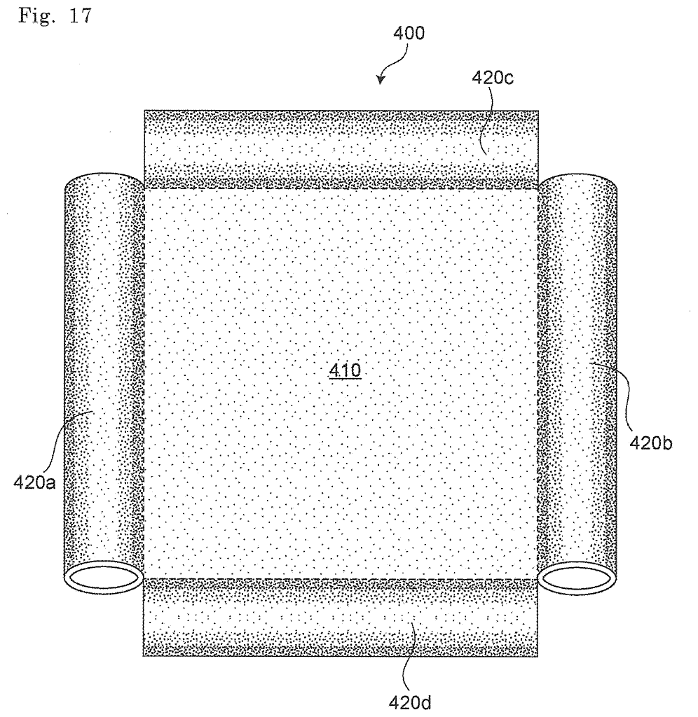

A fabric having a smooth structure was produced by a double 28 G knitting machine using piezoelectric yarns (PLLA84T72DTY) in the same manner as in Examples and Comparative Examples, and a sample 400 for an antibacterial test illustrated in FIG. 17 was produced.

The sample 400 has a square (30 mm×30 mm) sample main body 410. Tubular loops (or tubes) 420a to 420d formed by bending and stitching a fabric are arranged on each side of the sample main body 410.

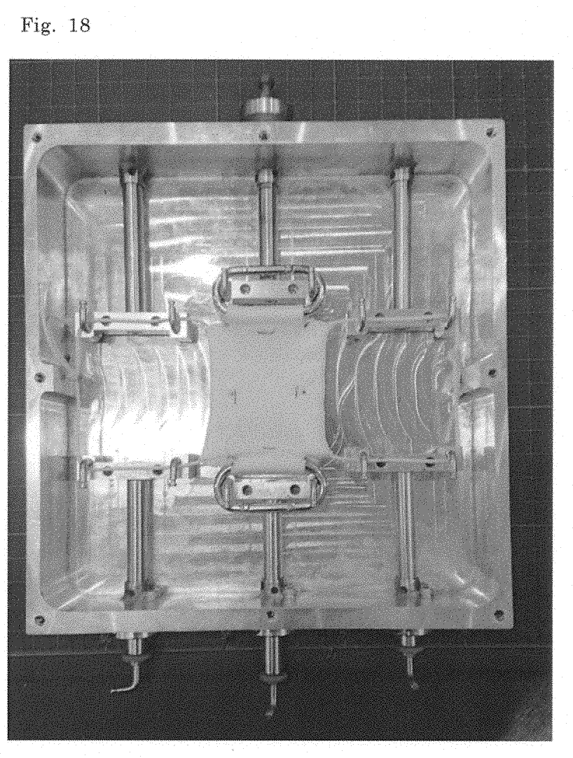

The sample 400 can be placed in an antibacterial test chamber by passing a string (kite yarn) through the longitudinal loops (420a, 420b) and passing a carabiner through transverse loops (420c, 420d) (refer to FIG. 18).

The main body 410 of the sample 400 is an antibacterial test region, and the sample 400 is placed in an antibacterial test chamber with the wale direction of the fabric as the longitudinal direction and the course direction of the fabric as the transverse direction (refer to FIG. 18).

(Test Conditions)
Bacterial liquid conditions

Strain: Escherichia coli K 12 strain

Medium: 5% concentration LB medium

Bacterial liquid concentration: 10⁶CFU/mL

Inoculation amount of bacterial liquid: 0.2 mL
Culture conditions

Culture environment: 37° C. incubator

Culture time: 18 hours
Sample loading conditions

Initial: A predetermined amount of tension is applied as an initial strain in the transverse direction (course direction) (5% elongation).

Expansion and contraction: Tension is applied as a maximum strain in the longitudinal direction (wale direction) at the maximum elongation rate (%) shown in Table 1.

Operation frequency: 0.2 to 3 Hz

Amplitude: 10 mm

(Test Procedure)

(1) Sample Set

A kite yarn was passed through the left and right loops (420a, 420b) of Sample 400 (refer to FIG. 17), and a carabiner was set through the upper and lower loops (420c, 420d).

The sample 400 was set in the center lane (refer to FIG. 18) of the antibacterial test chamber via carabiners provided in the loops 420c and 420d, and the kite yarn was hooked on the adjacent left and right lanes.

Shaft positions of the left and right lanes were changed to apply tensile strain as initial strain to the sample main body 410 in the transverse direction.

After the initial strain in the transverse direction was set, the tensile strain in the longitudinal direction at the maximum stroke was applied under the above expansion and contraction conditions according to the maximum elongation rate (%) shown in Table 1.

The stroke cam was set to the maximum stroke position at the upper portion of the central lane in FIG. 18, and the shaft was fixed at the lower portion of the central lane, so that tensile strain was applied in accordance with the elongation rate (%) of each test condition.

(2) Bacterial Liquid Inoculation

Each sample was inoculated with a bacterial liquid under the above conditions.

(3) Culture

The antibacterial test chamber in which the sample was set was incubated simultaneously with expansion and contraction for 18 hours in an incubator.

(4) Sample Collection

Samples were collected after an 18 hour incubation. The sample was put into a tube for washing out. Furthermore, physiological saline (20 mL) for washing out was added, and the sample was washed out using a vortex.

(5) Preparation of Dilution Series and Smearing on Agar Medium

An optional dilution series was prepared from the washing solution of the sample using Easyspiral Dilute manufactured by Interscience, Inc., and smeared on an agar medium. The smeared agar medium was placed in a 37° C. incubator and incubated overnight.

(6) Counts

The number of colonies generated on the agar medium was counted.

As a comparison sample, a bacterial liquid was inoculated into a sample 400 similar to the above sample illustrated in FIG. 17 under the same conditions as above, and then the sample was incubated in an incubator for 18 hours without expansion and contraction. Colonies were then counted in the same procedure as described above.

The difference (absolute value) between the number of colonies (number of bacteria) when the sample was repeatedly expanded and contracted for 18 hours and the number of colonies (number of bacteria) when the sample was allowed to stand for 18 hours in the comparison sample was evaluated as the result of the antibacterial test (refer to Table 1).

From the results of the antibacterial test shown in Table 1, it was found that the mask of Examples 1 to 6 of the present disclosure had an antibacterial effect of 4 times to about 6 times as compared with the mask of the conventional shape of Comparative Example 1.

As described above, the mask of the present disclosure has safety without using a drug such as an antibacterial agent and/or an antiviral agent, and is excellent in antibacterial property and/or antiviral property, dust collection property, comfort, and the like. Accordingly, the mask of the present disclosure can be used as an antimicrobial mask, an antiviral mask, a medical mask and/or a dustproof mask, or the like.

### DESCRIPTION OF REFERENCE SIGNS

1, 2: Yarn
10: Potential generating filament (or electric field forming filament)
100: Dielectric
110: Mask
101: Main body (or mask main body)
102: Body contact member
103: Lining
104: Stitched portion
105: Friction material
106: Wire
111: First dart
112: Second dart
113: Third dart
114: Fourth dart
115: Fifth Dart
121: Stitch (stitch of first dart 111)
122: Stitch (stitch of second dart 112)
123: Stitch (stitch of body contact member 102)
124: Stitch (stitch of fourth dart 114)
125: Stitch (stitch of fifth dart 115)
126: Stitch (stitch of stitched portion 104)
127: Stitch (stitch of friction material 105)
200: Auxiliary tool
400: Sample
410: Sample main body
420: Loop (or tube)
900: Stretching direction
910A: First diagonal line
910B: Second diagonal line

What is claimed is:

1. A mask comprising:
a body including a yarn comprising a potential generating filament; and
at least one dart that extends from an edge portion of the body towards a central portion of the body.

2. The mask according to claim 1, wherein the yarn is constructed to generate a potential by expansion and contraction and/or vibration of at least the central portion of the body.

3. The mask according to claim 1, wherein the dart is a first dart that extends from the edge portion on an upper side of the body towards the central portion of the body, and the mask further comprises:
a second dart that extends from the edge portion on a lower side of the body towards the central portion of the body.

4. The mask according to claim 3, wherein the first dart and the second dart are aligned with each other along a virtual line connecting a center of the edge portion on the upper side of the body and a center of the edge portion on the lower side of the body.

5. The mask according to claim 3, further comprising at least one third dart that extends from the edge portion on at least one of a left side or the edge portion on a right side of the body towards the central portion of the body.

6. The mask according to claim 5, wherein the first dart, the second dart and the at least one third dart are respectively disposed so as to face the central portion of the body, and wherein respective ends of the first dart, the second dart and the at least one third dart face the central portion of the body and are spaced apart from each other.

7. The mask according to claim 6, wherein the yarn is constructed so as to generate a potential from expansion and contraction and/or vibration of the body in a region inside the respective ends of the first dart and the second dart and the at least one third dart.

8. The mask according to claim 1, further comprising a body contact member, wherein the body contact member extends in a string shape or a band shape from the edge portion of the body and is constructed to be fixed to an ear of a wearer of the mask.

9. The mask according to claim 1, further comprising a body contact member, wherein the body contact member extends in a string shape or a band shape from the edge portion of the body and is constructed to be fixed to a back of a head of a wearer of the mask.

10. The mask according to claim 8, wherein the body contact member is provided at the edge portion on the upper side and/or lower side of the body.

11. The mask according to claim 10, wherein the body contact member is provided at the edge portion on at least one of the left or right side of the body.

12. The mask according to claim 8, wherein the body contact member is provided along an entirety of the edge portion of the body.

13. The mask according to claim 8, further comprising a friction material on at least a part of a surface of the body contact member.

14. The mask according to claim 8, wherein the body contact member includes a wire.

15. The mask according to claim 14, wherein the wire is positioned along the edge portion on the upper side of the body.

16. The mask according to claim 14, wherein the wire is positioned along the edge portion on the lower side of the body.

17. The mask according to claim 14, wherein the wire is positioned along the edge portion on at least one of the left or right of the body.

18. The mask according to claim 1, wherein the potential generating filament comprises a piezoelectric material.

19. The mask according to claim 18, wherein the piezoelectric material comprises a poly-L-lactic acid (PLLA).

20. The mask according to claim 18, wherein the piezoelectric material is free of an additive.

21. The mask according to claim 18, wherein the piezoelectric material contains a hydrolysis inhibitor.
